(19) United States
(12) Patent Application Publication
(10) Pub. No.: US 2026/0203453 A1
(43) Pub. Date: Jul. 16, 2026

(54) SYSTEM AND METHOD FOR GENERATING INTERACTIVE DISPLAYS AND MANUFACTURING PRINT, CUT, AND FOLD PRODUCTS

(71) Applicant: Zazzle Inc., Menlo Park, CA (US)

(72) Inventors: Leslie Young HARVILL, Olympia, WA (US); Matthew DIFONZO, Belmont, CA (US)

(21) Appl. No.: 19/383,190

(22) Filed: Nov. 7, 2025

Related U.S. Application Data
(60) Provisional application No. 63/745,571, filed on Jan. 15, 2025.

(51) Int. Cl. G06F 30/10; G06Q 50/04

(52) U.S. Cl. CPC G06F 30/10; G06Q 50/04

(57) ABSTRACT

In some embodiments, a computer-implemented method for creating and manufacturing interactive display products with layered embellishments comprises: receiving a layout file in a format capable of containing vector paths, layers, and human-readable annotations; processing the layout file to extract a design area paths of a design including safe, visible, and bleed areas, as well as physical geometry paths such as cut paths and fold paths; generating annotated data and instructions for folding and cutting a product based on the fold paths and cut paths, including fold order and fold geometry; constructing a 3D model of the product from the annotated data, wherein the 3D model includes representations of a physical substrate, material type, and thickness; based, on the annotated data, the 3D model, folding-cutting instructions and one or more embellishments, generating an annotated design file; and based on the annotated design file, generating automated manufacturing instructions.

### TECHNICAL FIELD

The present approach relates to digital design and manufacturing systems, specifically methods and systems for creating, processing, and rendering interactive 3D models of custom print, cut, and fold products with layered embellishments.

### BACKGROUND

The approaches described in this section are approaches that could be pursued but not necessarily approaches that have been previously conceived or pursued. Therefore, unless otherwise indicated, it should not be assumed that any of the approaches described in this section qualify as prior art merely by their inclusion in this section.

The field of interactive display and manufacturing has seen significant advancements. Traditional methods often rely on manual processes and lack the integration of various techniques, leading to inconsistencies and inefficiencies. Existing systems typically handle only specific types of items and do not accommodate a wide range of materials or methods.

There appears to be a significant difference between products designed by humans and those manufactured by manufacturers. Current solutions often involve separate processes, which can result in errors and misalignments, particularly when dealing with complex designs or multiple layers. These systems also lack a unified approach to managing and visualizing the final product, making it difficult for users to see how their designs will look once all elements are applied.

Therefore, there is a need for a more integrated and flexible system that can handle various materials and techniques, automate the manufacturing process, and provide accurate visual representations of the final product. This would streamline production, reduce errors, and enhance the user experience by allowing for more precise customization and visualization of the final product.

### SUMMARY

According to one aspect of the present approach, a computer-implemented method for creating and manufacturing interactive display products with layered embellishments comprises receiving a layout file in a format capable of containing vector paths, layers, and human-readable annotations. The method further includes processing the layout file to extract design area paths, such as safe, visible, and bleed areas, as well as physical geometry paths, including cut paths and fold paths.

The approach may also involve generating instructions for folding and cutting the product based on the extracted fold paths and cut paths, including determining the fold order and fold geometry. Furthermore, the method may include constructing a 3D model of the product from the annotated data, wherein the 3D model contains representations of the physical substrate, material type, and thickness. In manufacturing and printing, the substrate is the base material on which ink, adhesive, or another substance is applied. The choice of substrate is critical as it affects the printing method, ink type, and the final product's durability, appearance, and function.

Additionally, the present approach supports various embellishment types, including foil printing, engraving, etching, and blocking, and can process combinations of these embellishments. The method also performs output verification to ensure that the final product matches the design intent, utilizing automated verification methods.

The approach may further include preprocessing and rendering maps for different embellishment types and rendering them in hardware on a client device. It also validates the foldability of the design by constructing a graph and checking for self-intersections and locked areas. Physically based rendering may be used to represent various embellishment types in a unified rendering model, allowing users to interactively change key values and view an image of the valid physical product that may be manufactured.

Finally, the present approach may include generating automated manufacturing instructions based on the annotated design file.

### BRIEF DESCRIPTION OF THE DRAWINGS

The patent or application file contains at least one drawing executed in color. The Patent Office will provide copies of this patent or patent application publication with color drawings upon request and payment of the necessary fee.

The way the above-recited features of the present disclosure can be understood in detail, as well as a more particular description of the disclosure, briefly summarized above, may be had by reference to aspects, some of which are illustrated in the appended drawings. It is to be noted, however, that the appended drawings illustrate only typical aspects of this present disclosure and are therefore not to be considered limiting of its scope, for the present disclosure may admit to other equally practical aspects.

FIG. 1A is a block diagram showing an example environment for the interactive display and manufacture of products.

FIG. 1B depicts an example of database product definitions.

FIG. 1C depicts an example of a physical geometry cut path.

FIG. 1D depicts an example of a physical geometry fold path.

FIG. 1E depicts examples of a design area of fold orders.

FIG. 1F depicts an example of a physical geometry bend path.

FIG. 1G depicts an example of physical geometry substrates.

FIG. 1H depicts an example of design areas.

FIG. 1I depicts examples of design area embellishment annotations.

FIG. 1J depicts examples of output verifications.

FIG. 2A is an example flowchart of an example method for an interactive display and manufacture of print, cut, and fold products with layered embellishments.

FIG. 2B is an example flowchart of an example method for creating and manufacturing interactive display products with layered embellishments.

FIG. 2C is an example flowchart for an example method for interactive display and manufacture of print, cut, and fold paper products with layered embellishments.

FIG. 3 is a block diagram showing an example environment for designing and manufacturing products.

FIG. 4A is an example apparatus for generating interactive displays and manufacturing print, cut, and fold products.

FIG. 4B is a block diagram of the information flow in the presented system.

FIG. 5 is a block diagram that illustrates a computer system with which the techniques herein may be implemented.

All the drawings, descriptions, and claims in this disclosure are intended to present, disclose, and claim a technical system and technical methods in which specially programmed computers, using a special-purpose distributed computer system design, execute functions that have not been available before to provide a practical application of computing technology to the problem of machine learning model development, validation, and deployment. In this manner, the disclosure presents a technical solution to a technical problem, and any interpretation of the disclosure or claims to cover any judicial exception to patent eligibility, such as an abstract idea, mental process, method of organizing human activity, or mathematical algorithm, has no support in this disclosure and is erroneous.

### DESCRIPTION OF EXAMPLE EMBODIMENTS

The following description outlines numerous specific details to understand the present approach thoroughly. It will be apparent, however, that the present approach may be practiced without these specific details. In other instances, well-known structures and devices are shown in block diagram form to avoid unnecessarily obscuring the present approach.

Embodiments are described herein according to the following outline:
1.0. GENERAL OVERVIEW
   1.1. EXAMPLE NOVELTY FEATURES
   1.2. EXAMPLE BENEFITS
   1.3. PRINT, CUT, AND FOLD PRODUCTS WITH LAYERED EMBELLISHMENTS
      1.3.1. TECHNICAL PROBLEMS
      1.3.2. TECHNICAL SOLUTIONS
   1.4. LAYERED EMBELLISHMENTS
      1.4.1. TECHNICAL PROBLEMS
      1.4.2. TECHNICAL SOLUTIONS TO THE TECHNICAL PROBLEMS
   1.5. TECHNICAL EFFECTS
      1.5.1. TECHNICAL EFFECTS OF THE DISCLOSED METHOD
      1.5.2. TECHNICAL EFFECTS OF THE DISCLOSED APPARATUS
2.0. NOVELTY ASPECTS
   2.1. INTERACTIVE DISPLAYING AND MANUFACTURING OF PRINT, CUT, AND FOLD PRODUCTS WITH LAYERED EMBELLISHMENTS
   2.2. USE OF HUMAN-READABLE ANNOTATIONS IN DATA FORMATS FOR MANUFACTURING INSTRUCTIONS
   2.3. AUTOMATED FOLDING AND CUTTING GENERATION
   2.4. INTEGRATION OF MULTIPLE EMBELLISHMENT TYPES IN A SINGLE MANUFACTURING PROCESS
   2.5. 3D MODEL GENERATION FROM 2D LAYOUTS FOR VISUALIZATION AND VALIDATION
3.0. EXAMPLE EMBODIMENTS
   3.1. EXAMPLE SYSTEM
   3.2. EXAMPLE APPARATUS
   3.3. EXAMPLE METHOD CLAIMS
      3.3.1. FIRST EXAMPLE METHOD
      3.3.2. FIRST FLOWCHART EXAMPLE
      3.3.3. SECOND EXAMPLE METHOD
      3.3.4. SECOND FLOWCHART EXAMPLE
      3.3.5. THIRD EXAMPLE METHOD
      3.3.6. THIRD FLOWCHART EXAMPLE
   3.4. EXAMPLE APPARATUS CLAIMS
      3.4.1. FIRST EXAMPLE APPARATUS
      3.4.2. SECOND EXAMPLE APPARATUS
      3.4.3. THIRD EXAMPLE APPARATUS
4.0. COMPUTATION ENVIRONMENT
5.0. COMPUTER ENVIRONMENTS FOR THE INTERACTIVE DISPLAY AND MANUFACTURE OF PRODUCTS
6.0. DATABASE PRODUCT DEFINITIONS
7.0. PHYSICAL GEOMETRY CUT PATHS
8.0. PHYSICAL GEOMETRY FOLD PATHS
9.0. DESIGN AREA FOLD ORDERS
10.0. PHYSICAL GEOMETRY BEND PATHS
11.0. PHYSICAL GEOMETRY SUBSTRATES
12.0. DESIGN AREAS
13.0. DESIGN AREA EMBELLISHMENT ANNOTATIONS
14.0. OUTPUT VERIFICATION
15.0. CORRECTION AND TUNING OF THE PRODUCT VISUALIZATION
16.0. EXAMPLE INFORMATION FLOW
17.0. EXAMPLE COMPUTER ENVIRONMENTS
18.0. IMPLEMENTATIONS MECHANISMS

### 1.0. General Overview

In some implementations, the novelty of the approach lies in its comprehensive system and method for creating, processing, and validating interactive display and manufacturing instructions for print, cutting, and folding products with layered embellishments. Some key innovative aspects include a Unified Data Container, which will be described in detail later. The approach uses a digital container format to encapsulate all necessary information for manufacturing, including images, geometric transformation, geometry, time-based behaviors, and key-value pairs for pre-rendering, rendering, and manufacturing instructions. The unified approach ensures that all data required for the design, customization, and manufacturing processes are contained within a single file.

Another key innovative aspect includes Human-Readable Annotations. The system allows human-readable annotations within a vector-based file describing the design layout. For example, a designLayoutFile is used as the input to construct a data container, making it easier for humans and machines to interpret and manipulate the design and manufacturing instructions.

Other key innovative aspects include Automated Validation and Folding. The approach includes a method for validating the physical structure of the product by constructing a graph of nodes, arcs, and polytopes to simulate and verify the foldability and manufacturability of the design. The automated validation ensures that the design can be physically realized without errors.

Another key innovative aspect includes Physically Based Rendering (PBR). The system utilizes PBR techniques to render the final product accurately, incorporating various embellishment types, including foil stamping, embossing, debossing, and spot UV printing. This ensures that the visual representation of the product matches the physical output.

Other key innovative aspects include Preprocessing for Embellishments. The approach includes a preprocessing step to handle different embellishment types within the rendering model. This allows for accurately representing complex, layered products without the need for separate geometry and shaders for each embellishment type.

Other key innovative aspects include Interactive Customization and Visualization. The system provides an interactive interface that allows users to customize the product and view a 3D representation of the final product, including all embellishments and folds. This enhances the user's experience by providing a realistic preview of the customized product.

Another key innovative aspect is Automated Output Verification, which includes an automated process for verifying the output of the manufacturing process against the design specifications. This ensures that the final product matches the intended design, including color accuracy and the correct application of embellishments.

The approach offers a novel and comprehensive solution for designing, customizing, and manufacturing complex print, cut, and fold products with layered embellishments, ensuring accuracy, efficiency, and a high-quality user experience.

### 1.1. Example Novelty Features

The present approach introduces a unified data container format that encapsulates all necessary information for the design, customization, visualization, and manufacturing of print, cut, and fold products with layered embellishments. Unlike traditional systems that rely on fragmented files and separate workflows, this approach consolidates vector paths, images, geometric transforms, time-based behaviors, and manufacturing instructions into a single, extensible file. This integration streamlines the entire process, reduces the risk of errors, and enables seamless transmission of design data between users, designers, and manufacturers. The unified data container not only improves efficiency but also supports real-time updates and interactive customization, representing a significant advancement over prior art.

Another key aspect of novelty lies in the use of human-readable annotations within the design layout files. These annotations provide clear, standardized tags for cut, fold, and bend paths, as well as substrate properties and types of embellishment. By embedding these annotations directly into vector-based files, the system enables both human and machine interpretation, facilitating accurate parsing and processing of manufacturing instructions. This approach addresses the lack of standardized annotation schemes in existing solutions, minimizing miscommunication and ensuring that design intent is preserved throughout the manufacturing process.

The approach further distinguishes itself through automated generation and validation of folding and cutting paths. By constructing a fold graph model from the annotated layout, the system simulates and verifies the physical feasibility of the design, checking for self-intersections, locked areas, and compliance with geometric constraints. This automated validation replaces manual inspection, which is prone to error and inefficiency, and ensures that only manufacturable designs proceed to production. The use of graph-based modeling for foldability validation is a novel solution to a persistent challenge in the field. Another novel feature is the integration of multiple embellishment types within a single manufacturing workflow. The system supports a wide range of embellishments, including foil printing, engraving, etching, and blocking, and processes combinations of these techniques using preprocessing filters and physically based rendering models. This unified approach eliminates the need for separate handling of each embellishment type, allowing for the creation of complex, layered products with consistent quality and reduced production time. The flexibility to manage diverse embellishments within a single system is a significant improvement over the existing fragmented process.

Furthermore, the approach introduces advanced 3D model generation from annotated 2D layouts, enabling accurate visualization and validation of the final product before manufacturing. By constructing detailed 3D representations that incorporate substrate properties, material thickness, and embellishment layers, the system offers users realistic previews and interactive customization options. This capability bridges the gap between digital design and physical output, reducing discrepancies and enhancing customer satisfaction. The ability to simulate and validate the product in three dimensions is a novel contribution to the field. Automated output verification and correction further enhance the approach's novelty. The system compares manufactured products with their digital counterparts using computational methods and computer vision, identifying discrepancies and providing feedback for correction.

The automated quality control loop ensures high fidelity between the intended design and the physical product, reducing waste and improving overall quality. The incorporation of real-time feedback and correction mechanisms is a distinctive feature not found in conventional systems.

In some implementations, the client application for interactive customization and visualization represents another innovative aspect. Users can modify key product parameters in real time, with the system constraining changes to manufacturable options and providing immediate visual feedback. This interactive interface empowers users to explore design possibilities while ensuring that all customizations remain within manufacturing constraints. The combination of real-time customization, manufacturability validation, and high-fidelity visualization sets this approach apart from prior solutions.

Furthermore, the approach's extensible support for multiple file formats and substrate types, along with its parametric customization framework, enables broad applicability across various industries and product categories. The system accommodates diverse materials and design requirements, with annotation schemes that can be expanded to support new substrates and embellishments. This adaptability, combined with automated manufacturing instruction generation and real-time conversion to client-side rendering formats, positions the approach as a comprehensive and forward-looking solution for modern digital design and manufacturing challenges.

### 1.2. Example Benefits

In some implementations, the approach provides flexibility in materials. The system handles various materials with different substrates. For example, the system may handle multiple products, including paper, metal, cardboard, cloth, and others.

Furthermore, the approach facilitates Annotations and Data Formats, including human-readable annotations and flexible data formats, to encapsulate all necessary information for manufacturing.

The approach also allows for defining and tracking Fold and Cut Paths. The path definitions provide detailed explanations of fold and cut paths within the product, as well as their importance in determining the product geometry and ensuring correct manufacturing.

Moreover, the approach provides detailed Physical Substrate Information, including annotated material properties like thickness, to ensure accurate rendering and manufacturing.

Furthermore, the approach provides definitions of Embellishment Types. The system can handle multiple embellishment types and encode them in the design file for automated processing.

The approach also provides Output Verification. This includes an automated verification process to ensure the final product matches the design intent, including color and embellishment accuracy.

Furthermore, the approach provides 3D Modeling functionalities. This includes, for example, creating 3D models from 2D layouts to provide users with accurate visual representations and customization options.

The approach also provides the functionalities for automating and improving the manufacturing process, ensuring high-quality, customizable products, and the strategic importance of patenting the technology.

### 1.3. Print, Cut, and Fold Products With Layered Embellishments

### 1.3.1. Technical Problems

Several challenges persist in interactive display products, particularly in manufacturing products that require printing, cutting, and folding with layered embellishments. Creating such products often involves intricate designs that require precise folding, cutting, and embellishing processes. These processes can rarely be accurately translated from digital designs to physical products, ensuring that the final output matches the intended design. The complexity of these tasks increases with the addition of various embellishment types, such as foil printing, engraving, etching, and blocking, which demand meticulous attention to detail and precise execution.

Current industry solutions exhibit several shortcomings. Traditional methods rely heavily on manual intervention, where operators interpret design files and execute folding and cutting instructions based on their understanding of the design. This manual approach often leads to inconsistencies and errors, such as incorrect folds or misaligned cuts, resulting in products that do not meet quality standards.

Additionally, existing systems lack a unified approach to handling multiple embellishment types, resulting in fragmented processes that require separate handling for each embellishment. Such fragmentation increases the complexity of the manufacturing process and the likelihood of errors and inefficiencies.

### 1.3.2. Technical Solutions

The method and apparatus disclosed herein address these issues by providing a comprehensive system for creating and manufacturing interactive display products with layered embellishments. The system receives a layout file in a format that can contain vector paths, layers, and human-readable annotations. Furthermore, the system processes the layout file to extract design area paths, including safe, visible, and bleed areas, as well as physical geometry paths such as cut paths and fold paths. Additional information about bleed/visible/safe areas is provided in, for example, U.S. Pat. No. 8/856,160.

Moreover, the system generates instructions for folding and cutting the product based on the extracted paths, constructs a 3D product model from the annotated data, and supports various types of embellishment. Additionally, the system performs output verification to ensure the final product matches the design intent, preprocesses rendering maps for different embellishment types, validates the foldability of the design, and allows users to interactively change values and view an image of the valid physical product. The unified approach streamlines the manufacturing process, reduces errors, and enhances the quality and consistency of the final products.

### 1.4. Layered Embellishments

### 1.4.1. Technical Problems

Creating and manufacturing print, cutting, and fold paper products with layered embellishments presents several challenges. Traditional methods often involve manual processes that are time-consuming and prone to errors. These methods require significant skill and precision to ensure the final product meets the desired specifications. Additionally, the lack of interactive tools for visualizing and validating the design before manufacturing can lead to costly mistakes and material wastage.

The complexity of incorporating various embellishment layers, such as foil stamping, embossing, and cutting, further complicates the process, making it challenging to achieve consistent and high-quality results. Current solutions for designing and manufacturing such paper products have several disadvantages.

Manual methods lack the precision and repeatability required for high-quality production. Cutting, folding, and embellishing errors can result in significant material waste and increased production costs. Existing software tools often fail to provide comprehensive interactive design and validation support, resulting in a disconnect between the digital design and the physical product. Furthermore, these tools may not effectively integrate multiple embellishment layers, resulting in a final product that does not accurately reflect the intended design.

### 1.4.2. Technical Solutions to the Technical Problems

The herein-described system and method address these issues by providing a comprehensive solution for the interactive display and manufacture of print, cut, and fold paper products with layered embellishments. The system specifies the structure of a descriptive layout file, complete with human-readable annotations for cut, fold, and bend paths, as well as design areas, using specific tags for parsing and additional information. This structure specification provides a human-readable vector-based layout, including accurately scaled paths for cutting, scoring, folding, and bending. It includes paths describing design areas (i.e., areas for applied embellishments) as well as an accurately scaled legend for the product substrate(s). Each path and legend has a specification for its naming. The naming specification includes the addition of human-readable keywords.

A fold graph model is constructed from the descriptive layout, defining paths, nodes, arcs, and polytopes, and validating the fold graph to ensure the described cut and folded physical structure is valid. An interactive model is then constructed from the n-tree and fold graph for display, including rendering and time-based animations. Preprocessing filters handle sub-design areas and embellishment layers, and the system manufactures the described physical product using various techniques, including printing, foil stamping, embossing, and cutting. The product visualization is validated and corrected against the manufactured physical product, and a digital container file is constructed containing images, geometric transforms, geometry, time-based behaviors, and tags or scripts for pre-rendering, rendering, and a list of values. This digital container file, or output, is transmitted to a client application, allowing users to interactively change values and view an image of a valid physical product that may be manufactured.

### 1.5. Technical Effects

### 1.5.1. Technical Effects of the Disclosed Method

In some implementations, a method disclosed herein introduces a comprehensive approach to creating and manufacturing interactive display products with layered embellishments by leveraging a layout file that contains vector paths, layers, and human-readable annotations. The method allows for the precise extraction of design area paths, including safe, visible, and bleed areas, as well as physical geometry paths such as cut and fold lines. The method ensures accurate and consistent final product production by generating detailed instructions for folding and cutting based on these paths, including fold order and geometry.

Constructing a 3D model from the annotated data, which includes representations of the physical substrate, material type, and thickness, provides a realistic preview of the final product. This model supports various embellishment types, including foil printing, engraving, etching, and blocking, and combines these processes to enhance the product's visual and tactile appeal.

The method's output verification step ensures that the final product aligns with the design intent through automated verification methods, thereby reducing the likelihood of errors and enhancing quality control. Preprocessing, rendering maps for different embellishment types, and rendering them in hardware on a client device allows for efficient and accurate product visualization.

Validating the foldability of the design by constructing a graph and checking for self-intersections and locked areas ensures that the product can be physically assembled as intended. Using physically based rendering to represent various embellishment types in a unified rendering model provides a realistic and consistent visual representation of the product.

Allowing users to interactively change key values and viewing an image of the valid physical product that may be manufactured enhances the user experience by providing immediate feedback and customization options. Generating automated manufacturing instructions based on the annotated design file streamlines the production process, reducing the need for manual intervention and minimizing the risk of errors.

Overall, this method offers a robust and efficient solution for designing, visualizing, and manufacturing interactive display products with layered embellishments, ensuring high-quality output and a seamless user experience.

Furthermore, the computer-implemented method for the interactive display and manufacture of print, cut, and fold paper products with layered embellishment introduces a comprehensive approach to designing and producing complex paper products. The method ensures precise and clear communication of design intent by generating a Descriptive Layout File with human-readable annotations for cut, fold, and bend paths, as well as design areas, each with specific tags. Constructing a fold graph model from the descriptive layout, including defining paths, nodes, arcs, and polytopes, allows for accurate representation and validation of the physical structure, ensuring the design is feasible for manufacturing.

The validation step ensures that the described cut and folded physical structure is valid, preventing errors in the final product. Constructing an interactive model from the n-tree and fold graph for display, including rendering and time-based animations, provides a dynamic and intuitive way for users to visualize and interact with the design, enhancing user engagement and understanding.

Building preprocessing filters for handling sub-design areas and embellishment layers streamlines the manufacturing process by preparing the design for various embellishment techniques, such as printing, foil stamping, embossing, and cutting. This step ensures that the final product meets the desired quality and specifications.

The method also includes validating and correcting the product visualization against the manufactured physical product, ensuring consistency and accuracy between the digital and physical models. Constructing a digital container file that contains images, geometric transformations, geometry, time-based behaviors, tags, or scripts for pre-rendering, rendering, and a list of key values facilitates efficient data management and transmission.

Transmitting the digital container file or its output to a client application enables seamless integration with user interfaces, allowing users to interactively change key values and view an image of a valid physical product that can be manufactured. This interactive capability enhances user experience by providing real-time feedback and customization options, ultimately leading to a more efficient and user-friendly design and manufacturing process.

### 1.5.2. Technical Effects of the Disclosed Apparatus

In some implementations, an apparatus for creating interactive displays and manufacturing print, cut, and fold products with layered embellishments integrates multiple specialized modules to streamline the design and production process. The data processing unit receives layout files in formats that contain vector paths, layers, and human-readable annotations, ensuring compatibility with various design software and facilitating the import of complex designs. The Design Area Path module defines and processes design area paths, including safe, visible, and bleed areas, as well as physical geometry paths such as cut paths and fold paths, ensuring precise and accurate design specifications.

The fold and cut instruction module generates detailed instructions for folding and cutting, including fold order, fold geometry, and cut paths, which are crucial for maintaining the integrity and functionality of the final product. The 3D model construction module constructs 3D models from the annotated data, visually representing the final product, including the physical substrate, material type, and thickness. This enables the accurate visualization and validation of the design before manufacturing.

The physical substrate annotation module annotates the physical substrate, including material type and thickness, which is essential for determining the appropriate manufacturing processes and ensuring that the final product meets the desired specifications. The embellishment-processing module supports and processes various embellishment types, including foil printing, engraving, etching, and blocking, providing a wide range of customization options.

The output verification module ensures that the final product matches the design intent by performing output verification, which includes automated verification methods, thereby reducing errors and providing production consistency. The preprocessing module generates rendering maps for various embellishment types, enabling high-quality visualizations that accurately represent the final product when rendered on a client device.

The validation module validates the foldability of a design by constructing a graph and checking for self-intersections and locked areas, ensuring that the design can be physically realized without problems. The rendering module utilizes physically based rendering to represent various embellishment types within a unified rendering model, thereby providing realistic and accurate visualizations.

The client interaction module enables users to interactively modify key values and view an image of a valid physical product, thereby enhancing the user's experience through real-time feedback and visualization. Finally, the automated manufacturing instruction module generates automated manufacturing instructions based on the annotated design file, streamlining the production process and reducing the potential for human error. This comprehensive integration of modules within the apparatus significantly improves the efficiency, accuracy, and flexibility of creating and manufacturing interactive display products with layered embellishments.

More specifically, the apparatus for the interactive display and manufacture of print, cut, and fold paper products with layered embellishments includes several specialized modules that work together to streamline the design and production process. The descriptive layout module generates and processes layouts with human-readable annotations, ensuring clear communication of cut, fold, and bend paths and design areas through the use of specific tags for parsing and additional information. This improves the accuracy and efficiency of the design phase.

The fold graph construction module constructs a model from the descriptive layout, defining paths, nodes, arcs, and polytopes, and validating the fold graph. This ensures that the physical structure described by the layout is feasible and can be accurately manufactured. The interactive model module constructs and displays an interactive model from the n-tree and fold graph, including rendering and time-based animations, providing a dynamic and visual representation of the product.

The preprocessing filter module builds preprocessing filters for handling sub-design areas and embellishment layers, optimizing the design for various manufacturing techniques. The manufacturing system produces the described physical product using printing, foil stamping, embossing, and cutting techniques, ensuring high-quality output.

The validation and correction module validates and corrects the product visualization against the manufactured physical product, ensuring the final product matches the design specifications. The digital container file module constructs a digital container containing images, geometric transforms, geometry, time-based behaviors, tags, or scripts for pre-rendering, rendering, and a list of key values, facilitating the transfer of design data to client applications.

The user interaction module enables users to interactively modify key values and view an image of a valid physical product that can be manufactured, providing a user-friendly interface for customization and ensuring that the final product meets the user's requirements. This comprehensive apparatus enhances the overall efficiency, accuracy, and user experience in designing and manufacturing custom paper products with layered embellishments.

### 2.0. Novelty Aspects

Some of the novelty aspects lie in its comprehensive and integrated approach to creating, processing, and manufacturing interactive display products with layered embellishments. For example, the approach uses a digital container format to encapsulate all necessary information for manufacturing, including vector paths, layers, human-readable annotations, and key-value pairs. This unified approach ensures that all data required for the design, customization, and manufacturing processes is contained within a single file, streamlining the workflow and reducing potential errors.

Furthermore, the approach enables human-readable annotations within the data container, making it easier for both humans and machines to interpret and manipulate the design and manufacturing instructions. This feature enhances the system's flexibility and usability.

Moreover, the approach includes a method for automatically generating and validating folding and cutting paths based on the input data. This automation reduces the reliance on human operators, minimizes errors, and ensures that the final product matches the intended design.

Additionally, the approach can construct 3D models from the annotated data, providing accurate visual representations of the final product, including the physical substrate, material type, and thickness. This feature allows users to visualize and validate the design before manufacturing, enhancing the user experience and reducing the likelihood of errors.

Furthermore, the approach supports various embellishment types, such as foil printing, engraving, etching, and blocking, and can process combinations of these embellishments. This flexibility allows for the creation of highly customized and visually appealing products.

Moreover, the approach utilizes PBR techniques to render the final product accurately, encompassing various types of embellishments. This ensures that the visual representation of the product matches the physical output, providing a realistic and consistent visualization.

Additionally, the approach includes a preprocessing step to handle various types of embellishment within the rendering model. This allows for accurately representing complex, layered products without the need for separate geometry and shaders for each embellishment type.

Furthermore, the approach offers an interactive interface that allows users to customize the product and view a real-time 3D representation of the final product. This feature enhances the user's experience by providing immediate feedback and allowing for precise customization.

Moreover, the approach includes an automated process for verifying the output of the manufacturing process against the design specifications. This ensures that the final product matches the intended design, including color accuracy and the correct application of embellishments.

In addition, the approach validates the foldability of the design by constructing a graph and checking for self-intersections and locked areas. This ensures that the design can be physically realized without issues, reducing the likelihood of manufacturing errors.

### 2.1. Interactive Displaying and Manufacturing of Print, Cut, and Fold Products With Layered Embellishments

In some implementations, a system and method for the interactive display and manufacturing of print, cut, and fold products with layered embellishment are novel in the way they integrate various embellishment types and automate the folding and cutting processes. The use of a single-file format to encapsulate all necessary information for manufacturing and visualization is notable.

The process involves an inventive step, for example, combining multiple embellishment techniques (e.g., foil printing, engraving, etching, etc.) and automating the folding and cutting processes. The integration of human-readable annotations and the ability to generate 3D models from 2D layouts adds to the non-obviousness of the process.

The system has practical applications in customizing and manufacturing various products, including greeting cards, stickers, and other print products. The system performs the intended function of automating and enhancing the manufacturing process.

The subject matter of the present approach falls within the eligible categories of processes and machines. The subject matter does not claim abstract ideas, natural phenomena, or laws of nature.

### 2.2. Use of Human-Readable Annotations in Data Formats for Manufacturing Instructions

In some implementations, the use of human-readable annotations in data formats by a system and method to convey manufacturing instructions is novel. This approach enables humans and machines to interpret the data feature not commonly found in existing systems.

The idea of embedding human-readable annotations to facilitate both human and machine interpretation involves an inventive step. The approach simplifies the process of marking up and extracting information for manufacturing.

This feature helps ensure that manufacturing instructions are clear and easily interpretable, reducing errors and improving efficiency.

### 2.3. Automated Folding and Cutting Generation

In some implementations, a system and method's automated generation of folding and cutting paths based on input data formats is novel. This automation reduces the reliance on human operators and minimizes errors.

The system's ability to automatically generate and validate folding and cutting paths involves an inventive step. Using geometric and kinematic models to ensure the validity of the folds adds to the non-obviousness. This feature is highly useful in automating the manufacturing process, ensuring accuracy, and reducing the need for manual intervention. Verifying the Descriptive Layout File and modifying it based on the production of a Physical Product based on a defined mapping between elements in the Physical Product and the Descriptive Layout File is novel.

The idea pertains to a process that automates and improves manufacturing.

### 2.4. Integration of Multiple Embellishment Types in a Single Manufacturing Process

In some implementations, a system and method's integration of various embellishment types (e.g., foil, UV printing, embossing, etc.) in a single manufacturing process is novel. The ability to handle multiple embellishments within one system is distinctive.

The system's flexibility in handling different embellishment types and using a unified file format to manage these processes involves inventive steps. The preprocessing of data to apply different embellishments is not immediately apparent.

This feature enables the creation of customized products with various embellishments, thereby enhancing both the product's aesthetic and functional qualities.

The idea pertains to a process and system for manufacturing custom products.

### 2.5. 3D Model Generation From 2D Layouts for Visualization and Validation

In some implementations, a system and method include generating 3D models from 2D layouts for visualization and validation purposes. The approach provides a comprehensive process to ensure the final product aligns with the design intent.

Using 3D models to validate the physical structure and appearance of the product involves an inventive step. The ability to simulate the manufacturing process and detect errors before production is not apparent. This feature helps provide accurate visual representations of the final product, ensuring customer satisfaction and reducing manufacturing errors.

Indeed, the present system and method include several patentable ideas that meet the criteria of novelty, inventiveness, utility, and subject matter eligibility. The ideas encompass a system and method for interactive display and manufacturing, utilizing human-readable annotations, automated folding and cutting path generation, integration of multiple embellishment types, and 3D model generation for visualization and validation.

### 3.0. Example Embodiments

### 3.1. Example System

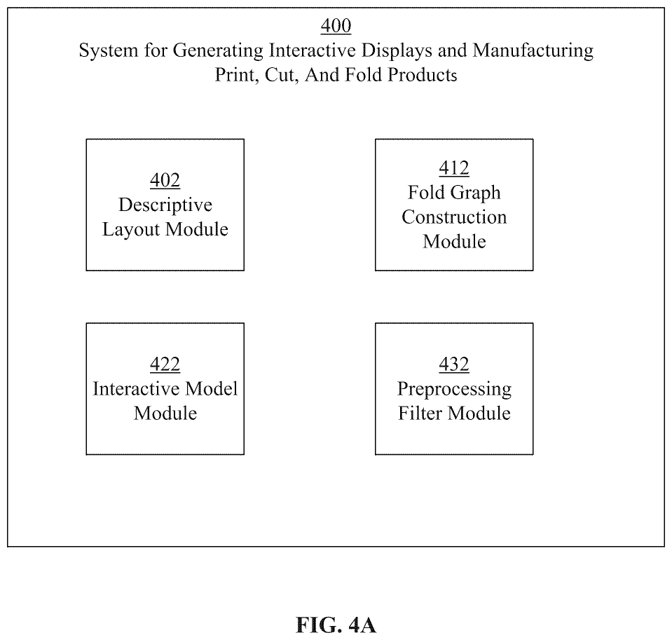

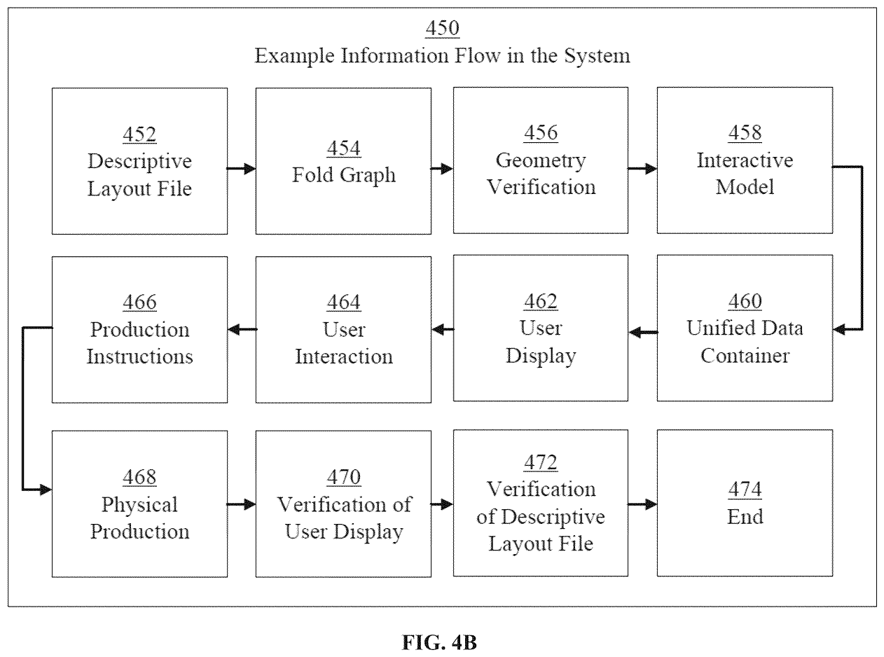

FIG. 4A is an example system 400 for generating interactive displays and manufacturing print, cut, and fold products. In some embodiments, the system for creating and manufacturing interactive display products with layered embellishments can be implemented using a variety of substrate materials, including cardboard, plastic, metal, and fabric. Each substrate offers unique properties for folding, cutting, and embellishing. The system is designed to receive a layout file in formats such as PDF, SVG, or OBJ, which contain vector paths, layers, and human-readable annotations.

A descriptive layout module 402 processes a layout file is to extract design area paths, including safe, visible, and bleed areas, as well as physical geometry paths such as cut and fold lines.

A fold graph construction module 412 generates instructions for folding and cutting the product based on these paths, including fold order and fold geometry. A 3D model of the product is constructed from the annotated data, representing the physical substrate, material type, and thickness. The system supports various embellishment types, including foil printing, engraving, etching, and blocking, and can process combinations of these embellishments. Output verification is also supported, ensuring the final product matches the design intent through automated verification methods.

Furthermore, the system may include preprocessing capabilities, generating rendering maps for different embellishment types and rendering them in hardware on a client device. The system validates the foldability of the design by constructing a graph and checking for self-intersections and locked areas. Physically based rendering is used to represent various types of embellishments within a unified rendering model, allowing users to interactively change values and view an image of the valid physical product that may be manufactured. Automated manufacturing instructions are generated based on the annotated design file.

In another embodiment, the system comprises an interactive model module 422 that includes a data processing unit configured to receive a layout file in a format capable of containing vector paths, layers, and human-readable annotations. A design area path module defines and processes design area paths, including safe, visible, and bleed areas, as well as physical geometry paths such as cut paths and fold paths. A fold and cut instruction module generates instructions for folding and cutting, including fold order, fold geometry, and cut paths. The 3D model construction module builds 3D models from the annotated data, while the physical substrate annotation module annotates the physical substrate, including material type and thickness.

The embellishment processing module supports and processes various embellishment types, including foil printing, engraving, etching, and blocking. The output verification module ensures the final product matches the design intent, and the preprocessing module generates rendering maps for different embellishment types for rendering in hardware on a client device. The validation module checks the foldability of a design by constructing a graph and checking for self-intersections and locked areas. The rendering module uses physically based rendering to represent various embellishment types in a unified rendering model. The client interaction module allows users to interactively change values and view an image of a valid physical product. The automated manufacturing instruction module generates automated manufacturing instructions based on the annotated design file.

A preprocessing filter module 432 can be adapted to handle non-folding products, such as flat cards or posters, focusing on cutting and embellishing rather than folding. The system processes the layout file to extract cut paths and embellishment areas, generating instructions for cutting and applying embellishments. The 3D model construction module creates a visual representation of the product, showing the placement of embellishments. The output verification module ensures that the final product matches the design intent, and the preprocessing module generates rendering maps for the embellishments. The validation module checks for any potential issues with the cut paths, ensuring that the design can be accurately manufactured. The rendering module uses physically based rendering to provide a realistic preview of the product, and the client interaction module allows users to adjust and view the final design. Automated manufacturing instructions are generated to guide the production process, ensuring that the final product meets the specified requirements.

### 3.2. Example Apparatus

In some embodiments, an apparatus for creating interactive displays and manufacturing print, cut, and fold products with layered embellishments includes a data processing unit configured to receive a layout file in various formats such as PDF, SVG, or OBJ, which can contain vector paths, layers, and human-readable annotations. The design area path module within the apparatus can define and process design area paths including safe, visible, and bleed areas, as well as physical geometry paths such as cut paths and fold paths. This module can be adapted to handle different types of materials, ranging from thin paper to thick cardstock, and even non-paper substrates like bamboo or glass, ensuring versatility in the types of products that can be created.

In another embodiment, the fold and cut instruction module is designed to generate detailed instructions for folding and cutting, including fold order, fold geometry, and cut paths. This module can accommodate various folding complexities, from simple single folds to intricate multi-fold designs such as tri-folds or origami-inspired structures.

A 3D model construction module can then construct 3D models from the annotated data, visually representing the final product. This module can be enhanced to include different material properties, such as thickness and flexibility, to simulate the product's physical characteristics accurately. Additionally, the physical substrate annotation module can annotate the physical substrate, including material type and thickness, which ensures that the final product meets the desired specifications. This module can be adapted to handle a wide range of materials, including different types of paper, cardboard, and even more rigid materials like plastic or metal.

The embellishment processing module supports and processes various embellishment types, including foil printing, engraving, etching, and embossing. This module can handle different combinations of these embellishments, allowing for a high degree of customization and creativity in the final product.

The output verification module verifies output to ensure the final product matches the design intent. This module can include automated verification methods, such as comparing the final product to the 3D model to ensure accuracy.

The preprocessing module generates rendering maps for different embellishment types for rendering in hardware on a client device. This module can be adapted to handle different rendering techniques, ensuring that the final product is visually accurate and meets the desired quality standards.

The validation module validates the foldability of a design by constructing a graph and checking for self-intersections and locked areas. This module can be enhanced to handle different levels of complexity in the folding design, ensuring that even the most intricate designs are validated accurately.

The rendering module uses physically based rendering to represent various embellishment types in a unified rendering model. This module can handle different lighting conditions and material properties, ensuring the final product is rendered accurately.

The client interaction module allows users to interactively change values and view an image of a valid physical product. This module can be adapted to provide a user-friendly interface, allowing users to customize their designs and see real-time updates easily. User updates are performed by interactively changing key-value pairs in the Digital Model. The key-value pairs will enable the user to set customizable properties of a Physical Manufactured Product. Each user input is constrained, so the changed property may be manufactured. The key-value pairs in the Digital Model are mapped onto the key-value in the Product Description. The Product Description may be used to output manufacturing instructions by the automated manufacturing instruction module.

The automated manufacturing instruction module generates automated manufacturing instructions based on the annotated design file. This module can be configured to handle different manufacturing processes, ensuring that the final product is produced accurately and efficiently. The manufactured Physical Product may be used to validate the Interactive Digital Model and the Descriptive Layout File.

### 3.3. Example Method Claims

### 3.3.1. First Example Method

One of the disclosed computer-implemented methods provides a comprehensive solution for the interactive display and manufacture of print, cut, and fold products with layered embellishments. At its core, the method generates a unified data container file that encapsulates all information necessary for design, customization, visualization, and manufacturing. This unified file format consolidates vector paths, images, geometric transforms, time-based behaviors, and manufacturing instructions into a single, extensible file, streamlining the workflow and reducing the risk of errors associated with fragmented data sources.

A key step in the process involves generating a descriptive layout file that includes human-readable annotations for cut, fold, and bend paths, as well as design areas. These annotations use specific tags for parsing and provide additional information, making the layout file both machine-interpretable and easily understood by human operators. This approach ensures that all design elements and manufacturing instructions are clearly communicated and standardized throughout the process.

The method further constructs a fold graph model from the descriptive layout file. This model defines paths, nodes, arcs, and polytopes, representing the geometric and physical relationships within the product design. The fold graph serves as a foundation for validating the manufacturability of the product, ensuring that all cut, fold, and bend paths are feasible and correctly implemented.

Validation of the fold graph is a critical aspect of the method. The system checks for self-intersections, locked areas, and compliance with geometric constraints, ensuring that the product can be physically assembled without errors. This automated validation replaces manual inspection, increasing efficiency and reliability in the manufacturing process.

An interactive model is then constructed from the n-tree and fold graph, enabling display, rendering, and time-based animations. This model allows users to visualize the product in three dimensions, interact with its features, and observe how different design choices affect the outcome. The interactive model supports real-time customization and provides immediate feedback, enhancing the user experience.

Preprocessing filters are built to handle sub-design areas and embellishment layers, preparing the design data for manufacturing. These filters ensure that each embellishment type is accurately represented and applied, supporting complex, layered products. The system can manufacture (or cause manufacturing by others) a physical product, corresponding to the product, using a variety of techniques, including printing, foil stamping, engraving, etching, blocking, embossing, and cutting, based on the descriptive layout file, fold graph model, and interactive model.

The method also includes automated output verification and correction, validating and correcting the appearance of the product against the manufactured physical product. The unified data container file or its output can be transmitted to a client application, where users can interactively change key-values. The system applies constraints to ensure that only manufacturable options are presented and provides visual feedback in response to user modifications.

Additional features of the method include the use of spot color labels and specific tags for fold and bend amounts and directions in the descriptive layout file, definition of path types such as cut, visible, fold, bend, safe area, and bleed, and the use of standardized measurements. The interactive model applies behaviors based on key-value pairs for animations, and manufacturing may include the application of transparent layers to alter surface qualities, further enhancing the versatility and quality of the final product.

### 3.3.2. First Flowchart Example

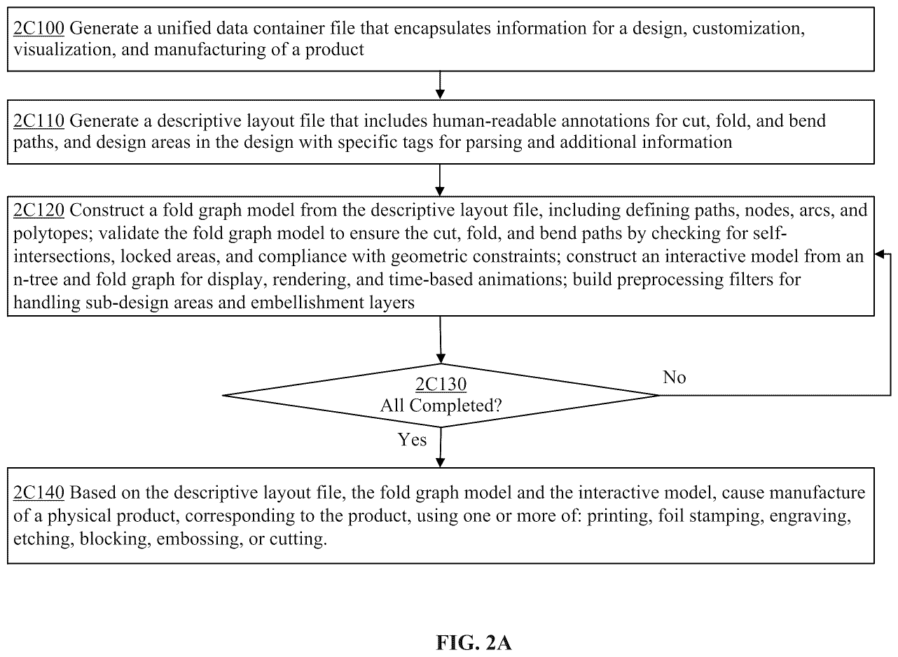

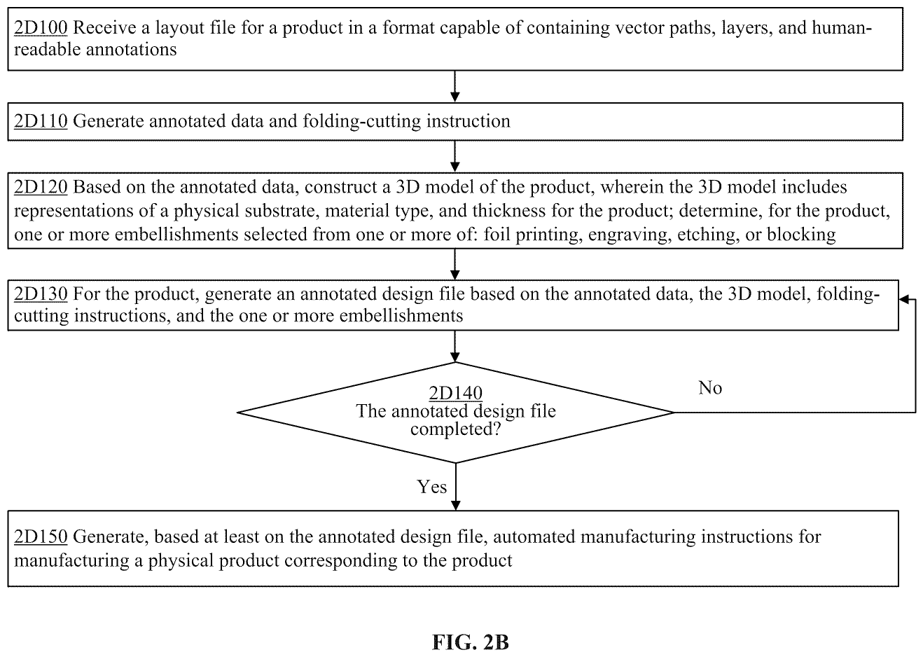

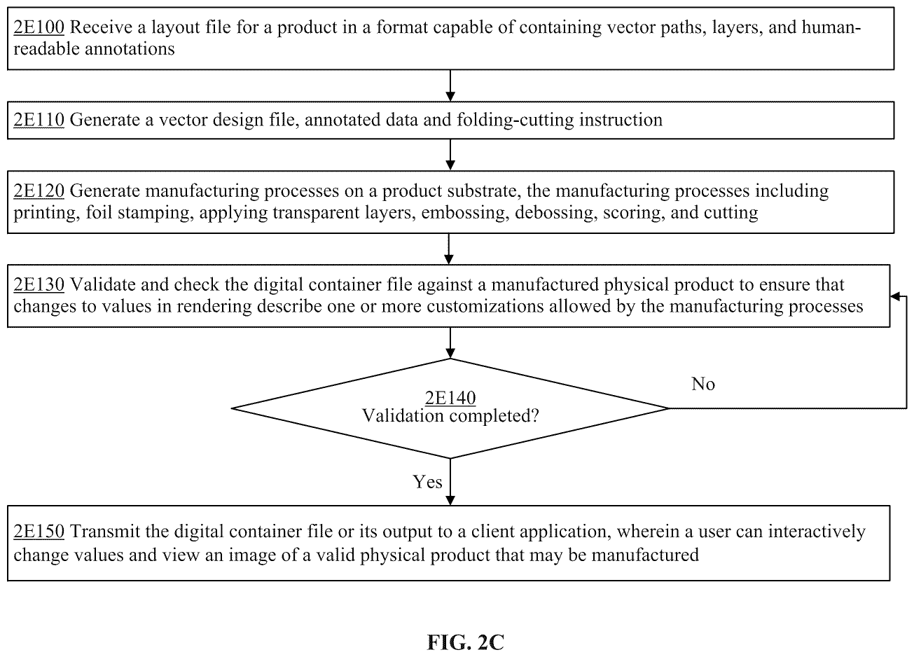

FIG. 2A is a first flowchart example of an example method for an interactive display and manufacture of print, cut, and fold products with layered embellishments. FIG. 2A illustrates a process for the interactive display and manufacture of print, cut, and fold products with layered embellishments.

The method may be executed by a data processing unit configured to generate (step 2C100) a unified data container file, which encapsulates all information necessary for design, customization, visualization, and manufacturing. This unified data container consolidates vector paths, images, geometric transforms, time-based behaviors, and manufacturing instructions into a single, extensible file.

Unified Data Container is a single, extensible digital file that encapsulates all information required for the design, customization, visualization, validation, and manufacturing of a product. The container consolidates, in one artifact:

Vector paths and layout annotations (e.g., cut, fold, bend, safe, visible, bleed) and associated metadata.

Images and textures, including embellishment maps and rendering assets.

Geometric transforms and geometry for interactive and 3D representations.

Time-based behaviors and animations for visualization and user interaction.

Key-value pairs and tags/scripts for pre-rendering, rendering, and manufacturing instructions.

Product-and substrate-specific properties (e.g., material type, thickness) and constraints.

By unifying these elements, the container enables interoperable transmission between users, designers, and manufacturers, supports real-time updates and interactive customization, and serves as the authoritative source for automated validation, output verification, and production instruction generation.

Additional information is included in, for example, U.S. patent Ser. No. 18/828,9317B2 and U.S. patent Ser. No. 18/738,921.

In step 2C110, a layout module generates a descriptive layout file containing human-readable annotations for cut, fold, and bend paths, as well as design areas, each marked with specific tags for parsing and additional information.

In step 2C120, a fold graph construction module constructs a fold graph model from the descriptive layout file, defining paths, nodes, arcs, and polytopes that represent the geometric and physical relationships within the product design.

Also, in step 2C120, a validation module validates the fold graph model by checking the cut, fold, and bend paths for self-intersections, locked areas, and compliance with geometric constraints.

Furthermore, in step 2C120, an interactive model module constructs an interactive model from an n-tree and the fold graph, supporting display, rendering, and time-based animations for user visualization and interaction.

Additionally, in step 2C120, a preprocessing filter module handles sub-design areas and embellishment layers and prepares the design data for manufacturing.

In step 2C130, the system tests whether all processing of step 2C120 has been completed. If it has, then the system proceeds to step 2C140. Otherwise, the system continues processing in step 2C120.

In step 2C140, a manufacturing module produces a physical product using various techniques, such as printing, foil stamping, engraving, etching, blocking, embossing, and cutting, based on the descriptive layout file, fold graph model, and interactive model.

The overall flow depicted in the drawing demonstrates how the system integrates data management, design validation, interactive visualization, and manufacturing processes to create customized print, cut, and fold products with layered embellishments.

### 3.3.3. Second Example Method

One of the disclosed computer-implemented methods provides a robust and integrated approach for creating and manufacturing interactive display products with layered embellishments. The process begins by receiving a layout file for a product, which is in a format capable of containing vector paths, layers, and human-readable annotations. This flexible input format enables designers to utilize industry-standard files, such as PDF, SVG, or OBJ, ensuring compatibility with a wide range of design tools and workflows. The inclusion of human-readable annotations, such as layer names, path names, and spot colors, further enhances the clarity and interpretability of the design data.

Once the layout file is received, the method processes the file to generate annotated data. This involves extracting design area paths, which include safe, visible, and bleed areas, as well as physical geometry paths such as cut paths and fold paths. These paths are crucial for defining the printable and manufacturable regions of the product, ensuring that all design elements are correctly positioned and that manufacturing tolerances are considered The extraction process leverages the embedded annotations to facilitate accurate parsing and interpretation by both human operators and automated systems.

The method then generates folding and cutting instructions for the product, based on the extracted fold paths and cut paths. This includes determining the fold order and fold geometry, which are critical for producing products with complex folding patterns, such as greeting cards, brochures, or packaging. By automating the generation of these instructions, the system reduces the risk of errors. It streamlines the transition from digital design to physical manufacturing, ensuring that the final product can be assembled as intended.

Based on the annotated data, the method constructs a 3D model of the product. This model includes representations of the physical substrate, material type, and thickness, providing a detailed and realistic visualization of the final product. The 3D model enables designers and users to assess the physical characteristics of the product and make informed decisions about materials and embellishments. The inclusion of substrate properties ensures that the model accurately reflects the product's manufacturability and durability.

The method further determines one or more embellishments for the product, selected from techniques such as foil printing, engraving, etching, and blocking. These embellishments are seamlessly integrated into the design and manufacturing process, enabling the creation of highly customized and visually appealing products. The system can support combinations of different embellishment types, enhancing the flexibility and creative potential of the manufacturing workflow.

For each product, an annotated design file is generated based on the annotated data, the 3D model, folding and cutting instructions, and the selected embellishments. This design file serves as a comprehensive blueprint for manufacturing the physical product, encapsulating all necessary information for accurate and efficient production. Automated manufacturing instructions are then generated based on the annotated design file, allowing for the precise production of a physical product that corresponds to the digital design.

The method also includes output verification to ensure that the physical product matches the intended design. This may involve automated verification methods, which compare the manufactured product to the annotated design file and identify any discrepancies. Preprocessing rendering maps for the embellishments is performed, and these maps are rendered in hardware on a client device, providing high-fidelity visualization of the product before it is manufactured. Physically based rendering is used to represent various embellishment types in a unified rendering model, offering realistic previews that accurately reflect the appearance and texture of the final product.

Foldability validation is another key aspect of the method. The system constructs a graph to check for self-intersections and locked areas, ensuring that the product can be physically assembled without issues. This validation step is crucial for preventing manufacturing errors and ensuring the structural integrity of products with intricate folding patterns or multiple layers.

Finally, the method allows users to interactively change key values and view an image of the physical product. This interactive capability empowers users to customize their products in real time, with the system applying constraints to ensure that all changes are manufacturable. The combination of automated design processing, advanced visualization, flexible embellishment integration, and interactive customization delivers a powerful solution for creating and manufacturing complex display products with layered embellishments, ensuring high quality, accuracy, and user satisfaction.

### 3.3.4. Second Flowchart Example

FIG. 2B is an example flowchart of an example method for creating and manufacturing interactive display products with layered embellishments. A computer processor, a computer server, or other computer-based device may perform the method steps. It is assumed in the following description that a computer server performs the method steps.

The process begins with a step 2D100, where a computer server obtains a layout file for a product in a format capable of containing vector paths, layers, and human-readable annotations.

Step 2D110 involves generating annotated data by extracting design area paths from the layout file. These paths include safe, visible, and bleed areas, as well as physical geometry paths such as cut paths and fold paths.

Also in this step, the computer server generates instructions for folding and cutting the product based on the extracted fold paths and cut paths, including determining the fold order and fold geometry.

Step 2D120 uses the annotated data to build a 3D model of the product. This model includes representations of the physical substrate, material type, and thickness, providing a detailed visualization of the product.

Also, in step 2D120, the computer server selects one or more embellishments for the product. These embellishments may include foil printing, engraving, etching, and blocking.

In step 2D130, an annotated design file is created based on, for example, the annotated data, the 3D model, folding-cutting instructions, and the selected embellishments. This file serves as a comprehensive blueprint for the product.

In step 2D140, the computer server tests whether the construction of the annotated design file has been completed. If it has, then the computer server proceeds to step 2D150. Otherwise, the computer server continues processing at step 2D130.

In step 2D150, the computer server generates automated manufacturing instructions based at least on the annotated design file, enabling the manufacturing of a physical product that corresponds to the digital design.

Each step in the flow chart represents a distinct phase in the method, illustrating the sequential and logical progression from initial design input to the automated production of a customized, embellished physical product.

### 3.3.5. Third Example Method

The disclosed computer-implemented method provides a comprehensive solution for the interactive display and manufacture of print, cut, and fold paper products with layered embellishments. At its core, the process constructs a digital container file that encapsulates all relevant data, including images, geometric transforms, geometry, time-based behaviors, and tags or scripts for pre-rendering, rendering, and a list of values. This digital container serves as a unified repository for all design and manufacturing information, streamlining the workflow and ensuring consistency throughout the process.

A vector design file is generated to describe the physical product intended for custom embellishment. This file attaches names and tags to groups of vectors, enabling precise identification and manipulation of design elements. The manufacturing processes supported by the method include printing, foil stamping, applying transparent layers, embossing, debossing, scoring, and cutting, allowing for the creation of highly customized and visually appealing products. The method further validates and checks the digital container file against the manufactured physical product, ensuring that any changes to values in rendering accurately reflect the customizations permitted by the manufacturing processes.

The digital container file or its output is transmitted to a client application, where users can interactively change values and view images of valid physical products that may be manufactured. This interactive capability empowers users to customize their products in real time, with the system applying constraints to ensure that all modifications are manufacturable. The method also includes the creation of a description layout file and a fold graph, representing the design layout with paths for cutting, folding, bending, and design areas, each annotated and tagged for parsing.

Validation of the fold graph is performed to ensure that the physical panels in a custom product can be printed and embellished, and that the structure of the folded product is not self-intersecting. An interactive model is constructed from an n-tree and the fold graph for display, allowing for validation of the design layout based on geometric and physical constraints and determination of relationships between design areas and physical product components. The method defines a ZigModel, ZigRoot, and ZigGeom for rendering geometry and time-based motion, including behaviors, coordinate spaces, and functions for assembling and traversing the n-tree.

Preprocessing filters are used to handle compositing and image operations, enabling a constant physically based rendering model for multiple products with complex embellishment layers. The ZigRoot is converted into widely used binary file formats, such as GLTF and GLB, which support real-time physically based rendering on the client application. Proprietary extensions are employed to preserve value references and embedded tags, ensuring the integrity and traceability of design data.

A user interface is provided in the client application for changing and updating value pairs within the digital model. User inputs are constrained to those that can be manufactured, and the interface presents both single and animated images of the user's changes, thereby enhancing the customization experience. The digital container file may further include metadata for tracking version history and changes, and may be encrypted for security purposes.

The vector design file supports multiple vector design file formats, including SVG and DXF, and may include color profiles and gradients for more detailed custom embellishments. The manufacturing processes may also include laser engraving and the use of eco-friendly inks and materials in the printing process, supporting sustainability and advanced customization.

Finally, validation and checking of the digital container file against the manufactured physical product can be performed using automated quality control checks with computer vision. This ensures that the final product aligns with the intended design, maintains high quality standards, and minimizes the risk of errors or inconsistencies in the manufacturing process.

### 3.3.6. Third Flowchart Example

FIG. 2C is an example flowchart for a method of interactive display and manufacture of print, cut, and fold paper products with layered embellishments. A computer processor, a computer server, or other computer-based device may perform the method steps. It is assumed in the following description that a computer server performs the method steps.

In step 2E100, a computer server receives a layout file for a product in a format that can contain vector paths, layers, and human-readable annotations. The computer server constructs a digital container file that contains all relevant data for the product. For example, the file may include images, geometric transforms, geometry, time-based behaviors, and tags or scripts for pre-rendering, rendering, and a list of values. The digital container serves as the central repository for all design and manufacturing information.

In step 2E110, the computer server generates a vector design file that describes the physical product intended for custom embellishment. The vector design file attaches names and tags to groups of vectors, enabling precise identification and manipulation of design elements for subsequent manufacturing steps.

In step 2E120, the computer server performs manufacturing processes on a product substrate. The manufacturing processes include printing, foil stamping, applying transparent layers, embossing, debossing, scoring, and cutting. These processes may include printing, foil stamping, applying transparent layers, embossing, debossing, scoring, and cutting. Each process is executed according to the specifications and instructions derived from the digital container and vector design files.

In step 2E130, the computer server validates and checks the digital container file against a manufactured physical product to ensure that changes to values in rendering describe one or more customizations allowed by the manufacturing processes. This step ensures that any changes to values in rendering accurately describe the customizations allowed by the manufacturing processes, and that the final product matches the intended design.

In step 2E140, the computer server tests whether the validation process has been completed. If it has, then the computer server proceeds to step 2E150. Otherwise, the computer server continues in step 2E130.

Finally, in step 2E150, the computer server transmits the digital container file or its output to a client application. In the client application, a user can interactively change values and view an image of a valid physical product that may be manufactured. This interactive capability allows for real-time customization and visualization, ensuring that user modifications remain within manufacturable constraints.

Each step in the flowchart represents a logical progression from initial digital design to interactive customization and final physical production, ensuring a seamless and accurate workflow for creating complex, embellished paper products.

### 3.4. Example Apparatus Claims

### 3.4.1. First Example Apparatus

In some implementations, an apparatus provides an integrated and automated solution for the interactive display and manufacture of print, cut, and fold products with layered embellishments. The apparatus features a data processing unit configured to generate a unified data container file. This file encapsulates all information necessary for design, customization, visualization, and manufacturing, consolidating vector paths, images, geometric transforms, time-based behaviors, and manufacturing instructions into a single, extensible file. This unified approach streamlines the workflow, reduces errors, and ensures that all relevant data is accessible throughout the product lifecycle.

A layout module is included to generate a descriptive layout file, which contains human-readable annotations for cut, fold, and bend paths, as well as design areas. These annotations utilize specific tags for parsing and provide additional information, making the layout file both machine-interpretable and readily comprehensible to human operators. The fold graph construction module then constructs a fold graph model from the descriptive layout file, defining paths, nodes, arcs, and polytopes that represent the geometric and physical relationships within the product design.

To ensure manufacturability, a validation module is provided to verify the fold graph by checking for self-intersections, locked areas, and compliance with geometric constraints in the cut, fold, and bend paths. This automated validation step is crucial for preventing errors and ensuring that only feasible designs are approved for production. The interactive model module constructs an interactive model from an n-tree and the fold graph, supporting display, rendering, and time-based animations. This enables users to visualize the product in three dimensions, interact with its features, and observe how different design choices affect the outcome.

The apparatus also includes a preprocessing filter module, which builds preprocessing filters for handling sub-design areas and embellishment layers. This capability supports the accurate representation and application of complex, layered embellishments. Finally, a manufacturing module is configured to produce the physical product based on the descriptive layout file, the fold graph model, and the interactive model. The manufacturing processes supported by the apparatus include printing, foil stamping, engraving, etching, blocking, embossing, and cutting, enabling the creation of highly customized and visually appealing products. This comprehensive integration of modules ensures a seamless transition from digital design to high-quality physical production.

### 3.4.2. Second Example Apparatus

In some implementations, an apparatus provides a comprehensive and automated solution for creating and manufacturing interactive display products with layered embellishments. At the front end, a file input module is configured to receive a layout file in a format that can contain vector paths, layers, and human-readable annotations. This ensures compatibility with industry-standard design formats, allowing for the seamless import of complex product designs.

Once the layout file is received, a processing module extracts the essential design area paths, including safe, visible, and bleed areas, as well as physical geometry paths such as cut paths and fold paths. This extraction is crucial for determining the printable and manufacturable regions of the product and for ensuring that all design elements are accurately positioned within manufacturing tolerances.

An annotation and instruction generation module then generates annotated data and detailed instructions for folding and cutting the product, including the determination of fold order and fold geometry. This module ensures that the manufacturing process is both precise and repeatable, reducing the risk of errors and enabling the production of intricate folding patterns and custom shapes.

A 3D model construction module is responsible for building a three-dimensional model of the product from the annotated data. This 3D model includes representations of the physical substrate, material type, and thickness, providing a realistic and detailed visualization of the final product. Such modeling is essential for validating the design and for enabling interactive previews and customizations.

The apparatus also includes a design file generation module, which creates an annotated design file that consolidates all relevant data, including the annotated data, the 3D model, folding and cutting instructions, and one or more embellishments. This comprehensive design file serves as the blueprint for manufacturing. Finally, a manufacturing instruction module generates automated manufacturing instructions based on the annotated design file, ensuring that the physical product is produced accurately and efficiently according to the digital design. This integrated approach streamlines the workflow from digital concept to finished product, supporting high levels of customization and quality control.

### 3.4.3. Third Example Apparatus

In some implementations, an apparatus provides an integrated solution for the interactive display and manufacture of print, cut, and fold paper products with layered embellishments. At its core, the apparatus includes a digital container file module that constructs a digital container file containing images, geometric transforms, geometry, time-based behaviors, and tags or scripts for pre-rendering, rendering, and a list of values. This digital container serves as a unified repository for all design and manufacturing data, streamlining the workflow and ensuring consistency throughout the product lifecycle.

A vector design file module is included to generate a vector design file describing the physical product for custom embellishment, with names and tags attached to groups of vectors for precise identification and manipulation of design elements. The manufacturing module is configured to perform a range of manufacturing processes on a product substrate, including printing, foil stamping, applying transparent layers, embossing, debossing, scoring, and cutting. These capabilities enable the creation of highly customized and visually appealing products.

The apparatus further comprises a validation module that validates and checks the digital container file against the manufactured physical product, ensuring that changes to values in rendering accurately reflect the customizations permitted by the manufacturing processes. A transmission module enables the digital container file or its output to be sent to a client application, where users can interactively change values and view images of valid physical products that may be manufactured.

Additional modules enhance the apparatus's functionality. A layout and fold graph module creates a description layout file and a fold graph for representing the design layout, including paths for cutting, folding, bending, and design areas with annotations and tags for parsing. The fold graph validation module ensures that physical panels in a custom product can be printed and embellished, and that the folded product's structure does not self-intersect. An interactive model module constructs an interactive model from an n-tree and the fold graph for display, validating the design layout based on geometric and physical constraints and determining relationships between design areas and physical product components.

The ZigModel, ZigRoot, and ZigGeom modules are configured for rendering geometry and time-based motion, including behaviors, coordinate spaces, and functions for assembling and traversing the n-tree. A preprocessing filter module handles compositing and image operations, enabling a constant physically based rendering model for multiple products with complex embellishment layers. The conversion module converts the ZigRoot into widely used binary file formats, such as GLTF and GLB, supporting real-time physically based rendering on the client application and preserving value references and embedded tags. The user interface module in the client application enables users to modify and update value pairs within the digital model, restricting inputs to manufacturable options and displaying both single and animated images of the user's changes.

Further enhancements include the ability to track version history and changes within the digital container file, as well as encryption for security. The vector design file module supports multiple file formats, including SVG and DXF, and can incorporate color profiles and gradients for more detailed, custom embellishments. The manufacturing module may also perform laser engraving and use eco-friendly inks and materials in the printing process. The validation module can perform automated quality control checks with computer vision, ensuring that the manufactured physical product matches the intended design and meets high standards of quality.

### 4.0. Computation Environment

A computer collaboration system is a networked, computer-based platform comprising one or more servers, services, databases, and client applications that coordinate to enable users, designers, and manufacturers to create, customize, visualize, validate, and produce products through shared digital assets and workflows. In operation, the system includes several components, examples of which are described below.

Front-end client applications (e.g., web, mobile, or desktop) through which users interact, submit designs, change key values, and review visualizations and animations of products.

Core services that process layout files with vector paths and human-readable annotations, generate and validate fold graphs, construct interactive 3D models, manage unified data containers, and produce automated manufacturing instructions.

Data tier components that include product option frameworks and databases for key-value pairs, user profiles, transaction data, and design assets, ensuring persistent, versioned, and secure storage of collaboration artifacts.

Rendering and visualization services that support physically based rendering, preprocessing of embellishment maps, and real-time, hardware-accelerated client display.

Manufacturing orchestration services that translate annotated design files into production instructions for printing, cutting, folding, and applying embellishments, and that perform output verification using automated methods.

Communication and security layers that handle authenticated data exchange, encryption of digital containers, and controlled access to design and production resources across users and roles.

Collectively, the computer collaboration system integrates design authoring, manufacturability validation, interactive visualization, data management, and production control to provide a unified, end-to-end collaborative environment for creating and manufacturing print, cut, and fold products with layered embellishments.

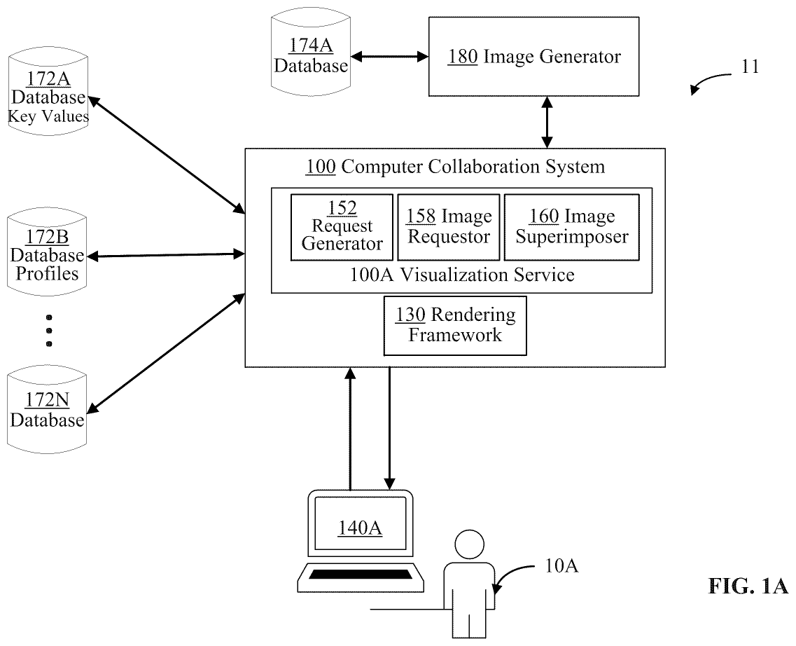

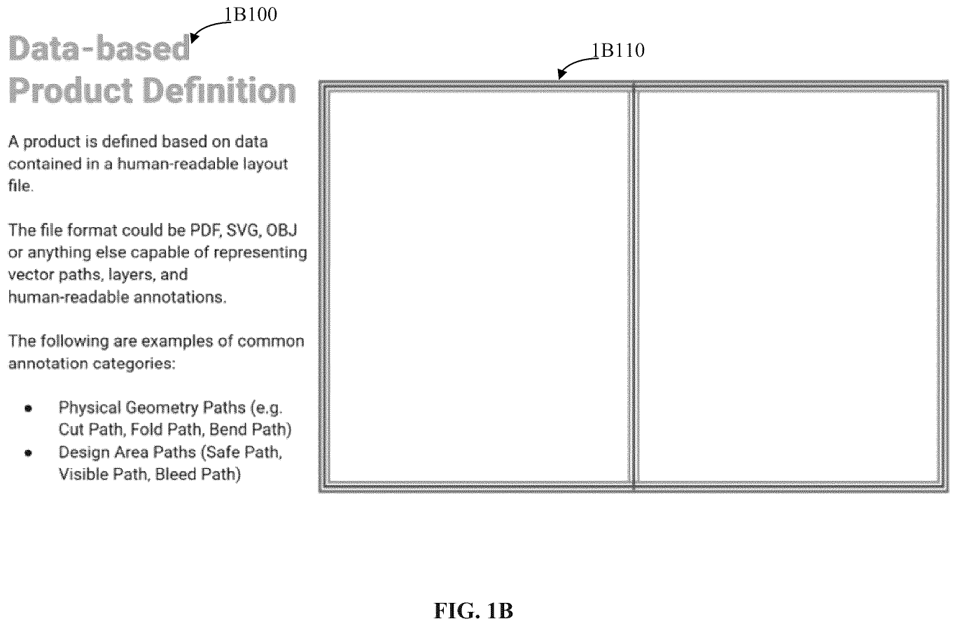

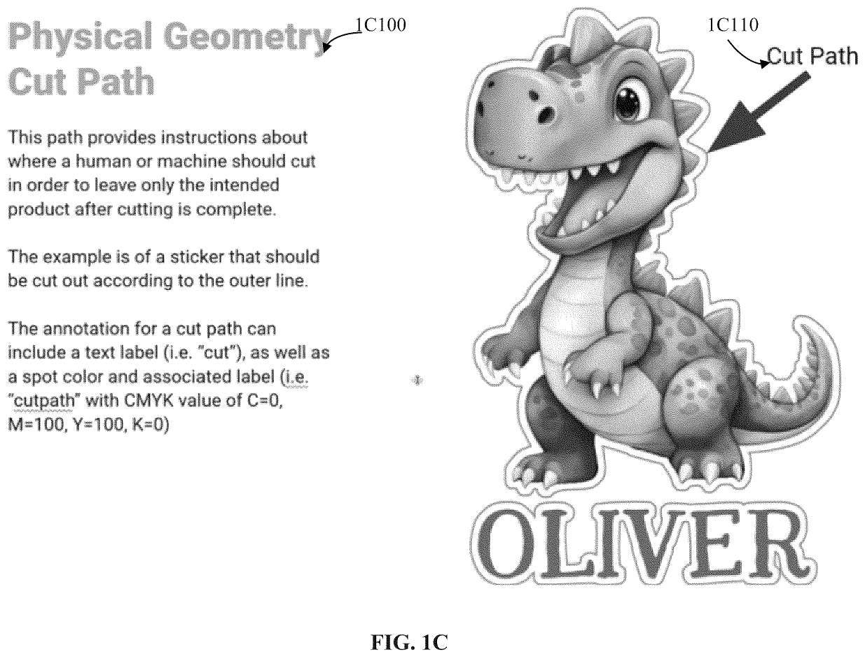

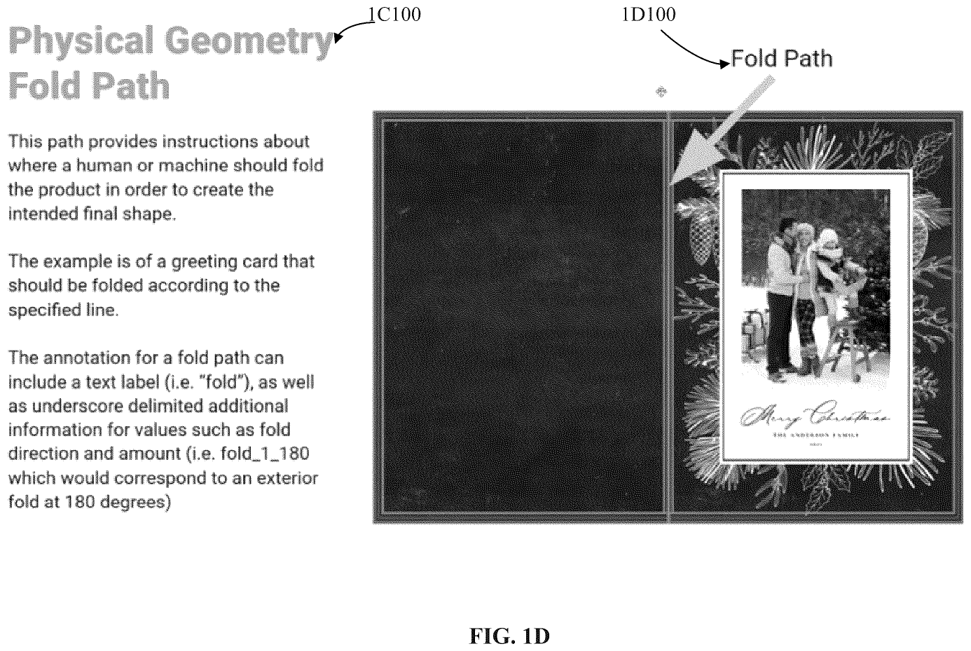

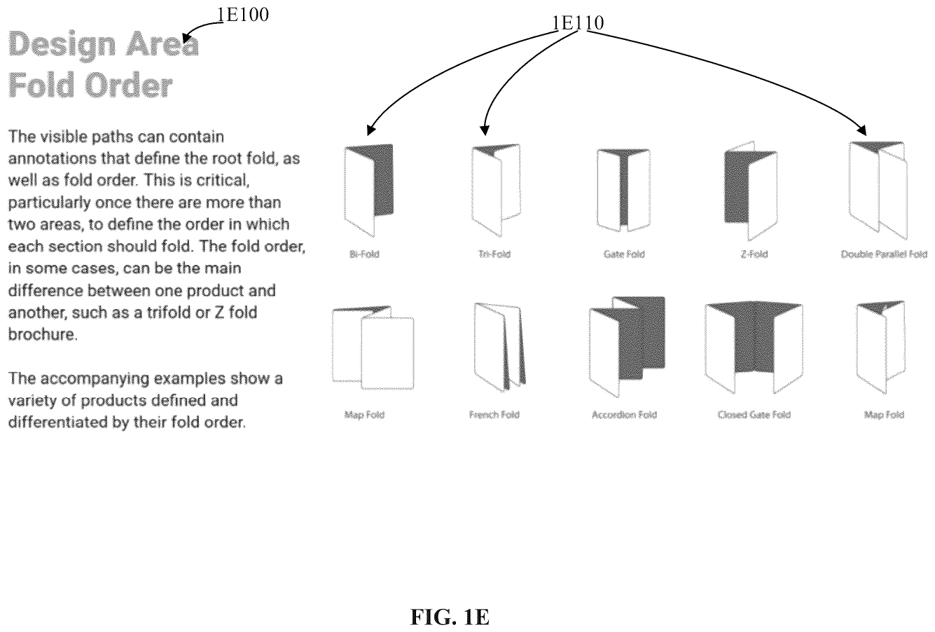

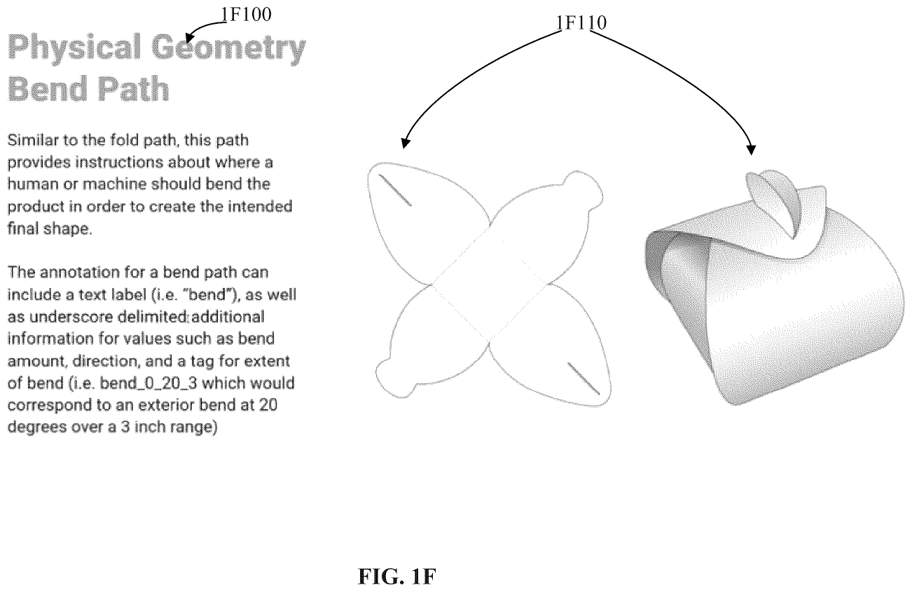

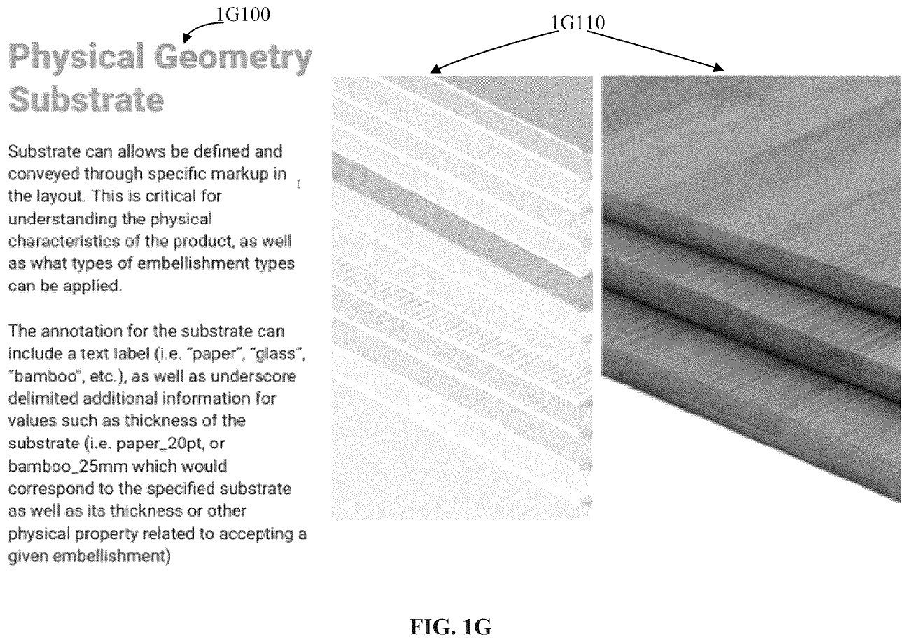

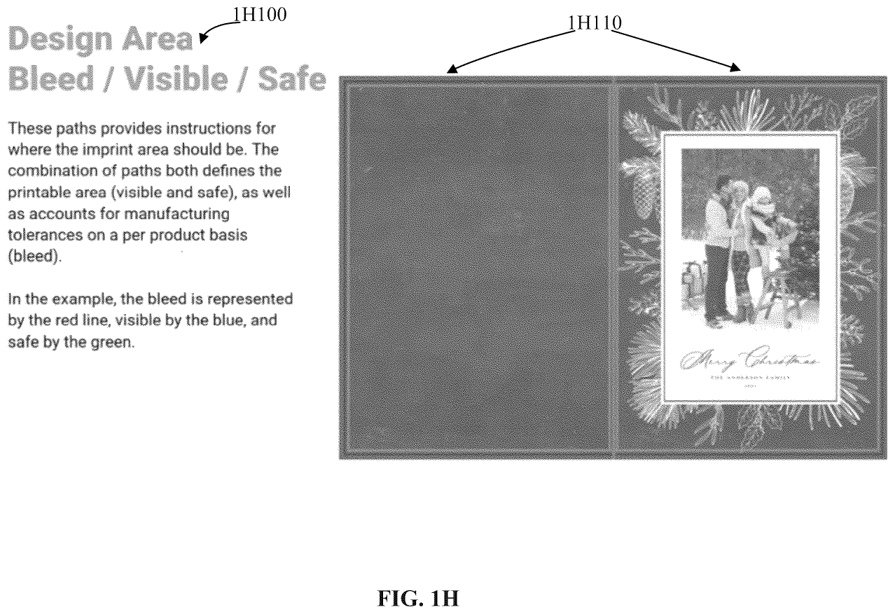

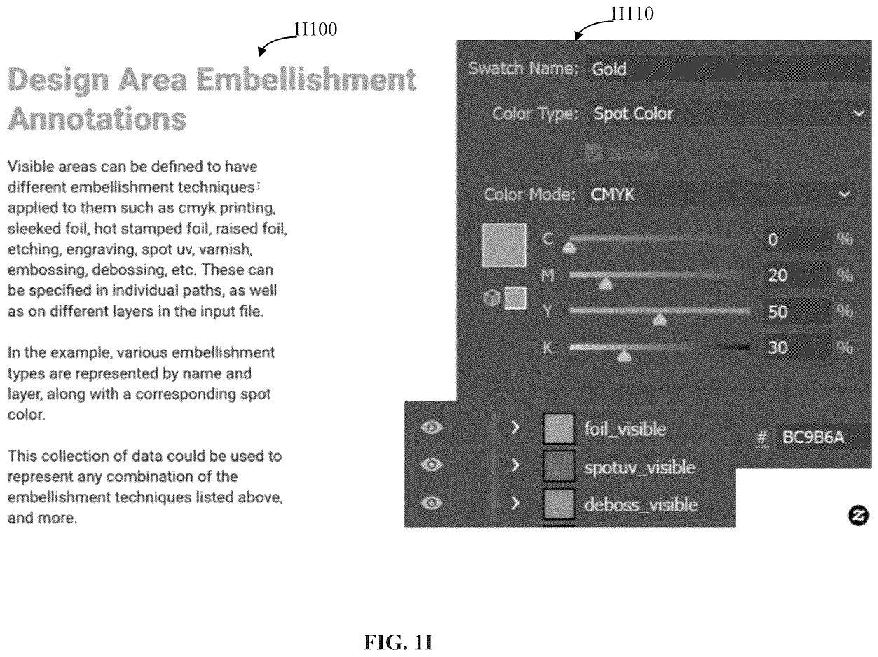

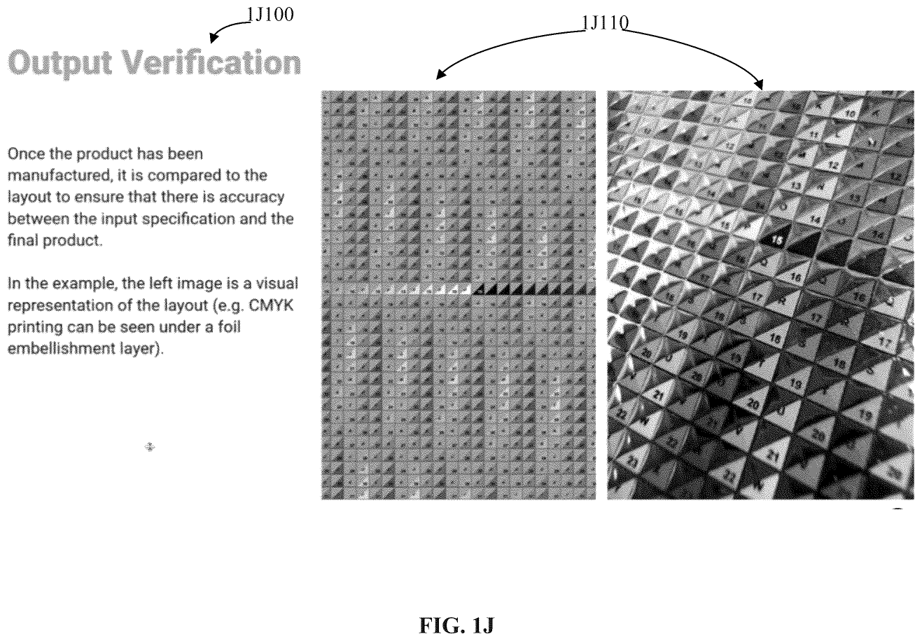

FIG. 1A is a block diagram showing an example of environment 11 for the interactive display and manufacture of products. Environment 11 depicted in FIG. 1A is configured to perform contextual resizing and filling in a design area. One of the elements of environment 11 is a computer collaboration system 100, described in detail later.

In some implementations, computer collaboration system 100 comprises a visualization service 100A, comprising a request generator 152, an image requestor 158, an image superimposer 160, and a rendering framework 130 (described in detail later). All components are described in detail later. Image requestor 158 may receive requests to generate a markup. Image superimposer 160 may be configured to superimpose a markup onto a customized product, as described later.

Collaboration system 100 may also include other components, examples of which are described later.

In some implementations, environment 11 also includes a database 172A storing key-value pairs (described later), a database 172B storing user profiles (described later), and one or more other databases 172N for storing additional information used by various components of environment 11 and/or computer collaboration system 100.

Environment 11 may also include a database 174A or a distributed or cloud-based system that can be used as storage for, e.g., billions of digital images, such as publicly available images. Such images may be downloaded from public resources, databases, and other repositories. For example, the images may be downloaded from the Internet and represent part of the DALL-E system.

Images stored in database 174A or some other storage included in environment 11 may be used by an AI-based image generator 180. AI-based image generator 180 may be an AI-based application configured to, for example, implement the stable diffusion approach for generating markup images or synthesizing images in response to a textual query.

### 5.0. Computer Environments for the Interactive Display and Manufacture of Products

In some implementations, a system and method for interactive display and manufacturing of printed, cut, and folded paper products with layered embellishments are disclosed. Examples of folds may include a paper fold, a card fold, a metal fold, a plastic fold, a cloth fold, and the like. The folds may include foldable metal objects, as well as bent or otherwise pleated or crinkled objects.

The custom products may also include layered embellishment. The embellishment may be printed on the sides of the product. The printing may be executed using colors from a CMYK (Cyan, Magenta, Yellow, and Key) color model.

Embellishments may be performed using various techniques, including oil printing, engraving, etching, blocking, etc. Various embellishment techniques are described in, for example, U.S. patent application Ser. No. 17/827,720, Ser. No. 17/827,721, Ser. No. 17/827,722, Ser. No. 17/827,723, Ser. No. 17/827,724, and Ser. No. 17/827,725.

Additional techniques have been described in U.S. Pat. No. 8,856,160 (“Product Options Framework and Accessories”) and U.S. patent application Ser. No. 18/738,807.

### 6.0. Database Product Definitions

Data-based products are products whose definition, configuration, and manufacturability are captured and driven by structured digital data rather than ad hoc specifications or purely manual instructions. In this context, a data-based product is defined by a product definition dataset that includes the items listed below.

Design data: vector paths and layout annotations specifying cut, fold, bend, safe, visible, and bleed areas, substrate types and thicknesses, and embellishment layers.

Parametric options: key-value pairs that encode customizable properties (e.g., size, color, material, finish, fold order) with constraints ensuring manufacturability.

Process instructions: machine-readable sequences for printing, cutting, folding, scoring, embossing, debossing, foil stamping, etching, and related steps derived from the design data.

Visualization assets: 3D models, textures, and rendering parameters enabling interactive previews and physically based rendering of the intended product.

Validation rules include geometric and physical constraints (e.g., foldability checks, self-intersection detection, and substrate-specific limits), as well as automated output verification criteria.

By storing and managing these elements in a unified product definition, data-based products can be programmatically generated, customized, visualized, validated, and manufactured with consistency across different substrates and embellishment workflows.

Additional components are defined in, for example, U.S. patent Ser. No. 18/856,160.

FIG. 1B depicts an example of data-based product definitions 1B100. In some implementations, a product is defined based on data contained in a human-readable layout field. The file format could be PDF, SVG, OBJ, or others capable of representing vector paths, layers, and human-readable annotations.

Examples of common annotation categories may include physical geometry paths (e.g., cut paths, fold paths, bend paths, and the like) and design area paths (e.g., safe paths, visible paths, bleed paths, and the like). Examples of different types of paths 1B110 have been described in, for instance, U.S. patent Ser. No. 8/856,160 (“Product Options Framework and Accessories”) and U.S. patent application Ser. No. 18/738,807.

### 7.0. Physical Geometry Cut Paths

FIG. 1C depicts an example of a physical geometry cut path 1C110. A physical geometry cut path (also described in 1C100) provides instructions about where a human or a machine should cut to leave only the intended product after cutting is complete. An example is a sticker that should be cut out according to the outer line. The annotation for a cut path can include a text label (i.e., a cut), a pot color, and an associated label (i.e., a cut path with a CMYK value of C=0, M=100, Y=100, K=0).

### 8.0. Physical Geometry Fold Paths

FIG. 1D depicts an example of a physical geometry fold path 1D100. A physical geometry fold path provides instructions about where a human or machine should fold the product to create the intended final shape. An example of the fold path is a greeting card that should be folded according to the specified line.

The annotation for a fold path can include a text label (i.e., “fold”) and underscore-delimited additional information for values such as fold direction and amount (i.e., “fold_1_180”, which would correspond to an exterior fold at 180 degrees).

### 9.0. Design Area Fold Orders

FIG. 1E depicts examples of a design area of fold orders 1E100. Visible paths can contain annotations that define a root fold and a fold order. That is critical, particularly once there are more than two areas, to determine the order in which each section should fold.

In some cases, the fold order can be the main difference between products, such as a trifold or Z-fold brochure. Element 1E110 depicts examples of different types of folds.

The examples shown in FIG. 1E shows a variety of products defined and differentiated by their fold order.

### 10.0. Physical Geometry Bend Paths

FIG. 1F depicts an example of a physical geometry bend path 1F100. Similar to the fold path, a physical geometry bend path provides instructions about where a human/machine should bend the product to create the intended final shape.

The annotation for a bend path can include a text label (i.e., bend), as well as underscore-delimited additional information for values such as bend amount, direction, and a tag for the extent of bend (i.e., bend_0_20_3, which would correspond to an exterior bend at 20 degrees over a 3-inch range). Element 1F110 depicts an example of folding.

### 11.0. Physical Geometry Substrates

FIG. 1G depicts an example of physical geometry substrates 1G100. Substrate can be defined and captured through specific markup in a layout. This is crucial for understanding the product's physical characteristics and the types of embellishments that can be applied. Element 1G110 depicts examples of different substrates.

Annotation for the substrate can include a text label (i.e., paper, glass, bamboo, and the like), as well as underscore delimited additional information for values such as thickness of the substrate (i.e., paper_20pt or bamboo_25 mm, which would correspond to the specified substrate as well as its thickness or other physical property related to accepting a given embellishment).

### 12.0. Design Areas

FIG. 1H depicts an example of design areas 1H100. More specifically, FIG. 1H shows various paths, including a design area path, a bleed area path, a visible area path, and a safe area path. These paths provided instructions on where the imprint area should be located. The combination of paths defines the printable area (visible and secure, as shown using an element 1H110) and accounts for manufacturing tolerances on a per-product basis (bleed).

In the example depicted in FIG. 1H, the bleed is represented by the red line; the blue line represents the visible area, and the green line represents the safe area.

### 13.0. Design Area Embellishment Annotations

FIG. 1I depicts examples of design area embellishment annotations 1I100. Visible areas can be defined as those with different embellishment techniques applied to them, such as CMYK printing, sleeked foil, hot-stamped foil, raised foil, etching, engraving, spot UV, varnishing, embossing, debossing, and the like. These can be specified in individual paths and layers in the input file.

The example represents various embellishment types by name, layer, and corresponding spot color. Example details are described in a table indicated by an element 1I110.

Data collection could represent any combination of the abovementioned embellishment techniques.

### 14.0. Output Verification

In certain situations, it is necessary to verify whether a customized object aligns with the provided customization guidance. This may include determining whether the actual outer part of the object matches the lines shown in the object view. This essentially involves verifying whether the advice provided by the manufacturer has been followed when producing the corresponding physical object.

The verification process is essential because if the actual product manufactured by the manufacturer does not meet the guidelines provided, then the problem needs to be corrected before orders for manufacturing physical products for customers are sent to the manufacturer. For example, in some situations, the manufacturer may have specific settings in their printers that cause scaling, stretching, or adjusting of the grid image. In contrast, the image is applied to the physical paper. These may cause some issues when the actual outer part of the object does not match the lines shown in the object view. For example, the manufacturer may be contacted and asked to turn off the settings that cause the image distortions.

In other situations, the manufacturer may have a different manufacturing process than the operators of the visualization platform expected. For example, if there are discrepancies between the physical product provided by the manufacturer and what was requested, then the issues need to be identified. The problems need to be, for example, reverse-engineered before they can be solved. This may sometimes require the operators to understand the manufacturing process before the problem is fully solved.

Additional details of the output verification process are described, for example, in U.S. patent application Ser. No. 17/827,720.

FIG. 1J depicts examples of output verifications 1J100. Once a product is manufactured, it is compared to the layout to ensure accuracy between the input specification and the final product.

In the depicted example, indicated using element 1J110, the left image represents the layout (e.g., CMYK printing can be seen under a foil embellishment layer).

### 15.0. Correction and Tuning of the Product Visualization

In some implementations, a system and method for the interactive display and manufacture of print, cut, and fold paper products with layered embellishment is corrected and tuned to enhance product visualization.

The process of correction and tuning of the product visualization may include the following steps:

Using a digital container format to construct a file containing images, geometric transforms, geometry, time-based behaviors, tags, or scripts for pre-rendering, rendering, and a list of key values.

A vector design file contains a description of a physical product for custom embellishment. The vector design file may attach names and tags to groups of vectors.

The described physical product is manufactured by printing various colors on the surface of the product substrate.

The next step involves foil stamping or debossing on the surface of the product substrate, applying transparent layers to the surface that alter its qualities, embossing or debossing the surface, or scoring or partially cutting the surface to allow for folding.

The next step involves cutting the product to its final shape or form, where a digital container file is constructed by checking the vector design file against the product description.

The digital container file may be rendered so that the changes to key values in rendering the file may describe the customizations allowed by the manufacturing process.

Each manufacturing process that alters its shape, form, and quality of reflected light can be validated and verified against the physical products it produces.

The digital container file, or its output, may be transmitted electronically to a client application, where a user can interactively change the key values and view an image of a valid physical product that can be manufactured.

The above process may also be captured using the following outline:
Descriptive Layout File:
   a. Human Readable
   b. Uses the ‘outside’ view by convention.
   c. Cut path
      i. Annotation
         1. ‘Cut’
         2. Spot Color label
   d. Fold path
      i. Annotation
         1. ‘Fold’
         2. Spot Color label
      ii. Additional tags
         1. Use ‘_’ for parsing
         2. Tag for fold amount/direction
   e. Bend Path
      i. Annotation
         1. ‘Bend
         2. Spot Color label
      ii. Additional tags
         1. Use ‘_’ for parsing
         2. Tag for bend amount/direction
         3. Tag for range
            a. Extent of bend.
   f. Design Areas
      i. Bleed Path
         1. Annotation
      ii. Visible Path
         1. Annotation
            a. Use ‘_’ for parsing
            b. Root Label
            i. Fold Root
            c. Fold Order
            i. FoldOrder_<value>
            d. FlipType
            i. How the sub-design may be flipped for viewing.
            e. Embellishment Layers
            i. Print Layer
            ii. Varnish (UV) layer
            iii. Foil
            iv. Embossing
            v. Flocking
            vi. Transfer
      iii. Safe Path
         1. Annotation
   g. Annotations
      i. Substrate Thickness
         1. Text and legend indicating the thickness of the substrate
      ii. Naming
         1. Layout naming conventions
The Product Description:
Constructing a model from the Descriptive Layout
   h. Building the Fold Graph
      i. Define a path
         1. A path has a name, the name may have additional tags
            a. ‘_’ is used for parsing between name and tag
            b. Tags indicate the type of path...
            i. Cut
            ii. Visible
            iii. Fold
            iv. Bend
            v. Safe Area
            vi. Bleed
         2. A path has a type, derived from the tags in the name found in the layout
            a. Define the path type
            i. Cut
            ii. Visible
            iii. Fold
            iv. Bend
            v. Safe Area
            vi. Bleed
         3. A path has a well-known system of measurement . . .
            a. Inches
            b. Millimeters
            c. Centimeters.
         4. A path is a list of 2d position coordinates
            a. x—horizontal position in coordinate system
            b. y—vertical position in coordinate system
      ii. Define a Fold Graph for representing the layout
         1. Has a name
         2. Has a substrate thickness.
         3. Has a list of nodes
         4. Has a list of arcs
         5. Has a list of polytopes
         6. Has a list of Kinematic Links.
         7. Has a list for each type of path . . .
            a. Has a list of visible paths
            b. Has a list of cut paths
            c. Has a list of sub cut paths
            d. Has a list of bleed paths
            e. Has a list of fold paths
            f. Has a list of bend paths.
      iii. Read each path from the layout, and add each one to its list.
      iv. If no cut paths exist.
         1. Find the visible path(s) that enclose other visible paths and are separate from other found enclosing paths
            a. Use the found visible path as the cut path.
            b. Multiple cut paths may exist as separate components of a container
            i. Top and bottom of sleeve containers
            ii. Container and lid.
            c. Add the found cut paths to the cut path list.
      v. Define a node in the graph
         1. Has 2-dimensional position
         2. Has a 3-dimensional folded Position
         3. Has a linked list of edges, each edge represented as one of a Arc pair.
      vi. Find each self-intersecting node of the cut path with itself.
         1. Add each intersecting node to the Fold Graph Node List
      vii. Find each intersecting node for fold and bend paths with the cut path.
         1. Add each intersecting node to the Fold Graph Node List
      viii. Subdivide each cut path by each Fold Graph Node in the list.
         1. Add each portion of the subdivided cut sub-path to a Sub Cut Path List.
      ix. Define an arc
         1. An arc contains a pair of links
            a. Each link refers to a Node
            b. Each link refers to a Polytope
         2. An arc has a name, the name may have additional tags
            a. ‘_’ is used for parsing between name and tag
            b. Tags indicate the type of path . . .
            i. Cut
            ii. Fold
            iii. Bend
         3. An arc has an n-tree level as an integer
      x. For each path in the Sub Cut Path List
         1. Add the path as an Arc in the Fold Graph Arc List
            a. Link each begin and end path point to its corresponding Fold Graph Node in the Fold Graph Node List.
            b. Set the arc type as a ‘cut’.
            i. Set the arc influence area to zero.
      xi. For each Fold path . . .
         1. Add the path as an Arc in the Fold Graph Arc List
            a. Link each begin and end path point to its corresponding Fold Graph Node in the Fold Graph Node List.
            b. Set the arc type as a ‘fold’.
            i. Set the arc influence variable to the Fold paths fold influence factor.
      xii. For each Bend path . . .
         1. Add the path as an Arc in the Fold Graph Arc List
            a. Link each begin and end path point to its corresponding Fold Graph Node in the Fold Graph Node List.
            b. Set the arc type as a ‘bend’.
            i. Set the arc bend amount to the Bend paths fold amount.
            ii. Set the arc bend influence variable to the Bend paths fold influence factor.
      xiii. Sort the Fold Graph Node list
         1. Sort the arc links for each node by angle in clockwise order.
            a. Angle is determined by the angle from the node position to the position of the node at the other end of the arc.
      xiv. Find the enclosed polytopes in the graph
         1. Define a polytope
            a. Contains a link to each of the edge pairs that form its boundaries.
            b. The Polytope has a name.
            i. ‘_’ is used for parsing between name and tag
            ii. Tags indicate the type of node . . .
            1. FoldRoot
            2. Embellishment type(s).
            c. Contains a list of child polytopes
            i. This is building a folding n-tree.
            d. Contains a link to paths associated with it.
            e. Contains a surface normal for its folded state
            f. Contains a centroid.
            g. Contains a fold order as an integer.
            h. Contains an n-tree level as an integer
            i. Contains a lockedDistance as a floating point number.
         2. For each node in the graph . . .
            a. Set the node as current.
            b. For each arc linked to that node . . .
            i. If the arc has no polytope link
            1. Create a temporary list of arcs
            2. Set the arc as the current arc.
            3. Add the current arc to the temporary list
            4. Find the end node for the current arc.
            a. Use the link for its pair.
            5. If the end node matches the current node, and the list contains more than two arcs . . .
            a. An enclosed polytope has been found
            i. Create a new polytope.
            ii. Link the polytope to the arcs in the temporary list.
            iii. Calculate the new polytope's area.
            iv. Add the new polytope to the Graph Polytope list.
            6. Find the next arc in the end node's sorted link
            7. If there is an arc
            a. If the current arc has no polytope link
            i. Branch to 2, above.
         3. For each path in the visible path list . . .
            a. Find a polytope that matches or contains the path.
            b. Link the found polytope to the visible path.
            c. Set the found polytope's name and tags to the name and tags of the visible path.
         4. For each path in the bleed path list . . .
            a. Find a polytope which substantially overlaps the path
            b. Link the found polytope to the visible path.
         5. For each path in the safe area path list . . .
            a. Find a polytope which contains the path.
            b. Link the found polytope to the visible path.
   i. Validating the Fold Graph.
      i. Each polytope in the Fold Graph represents a physical panel in the custom product which may be printed and embellished.
         1. When folded it will have an outward face and an inward face.
            a. Some portions of the face may not be visible depending on the folding pattern.
         2. The shape of the physical panel must be large enough to accommodate the fold or bend associated with it.
            a. The influence area of the associated fold or bend arc must be physically possible.
            i. For substrates with substantial thickness, for a fold of 90 degrees, the influence area must not be smaller than half the substrate thickness for non-elastic substrates.
            1. One test is to cut the polytope describing the panel by extending each fold or bend arc path perpendicularly into the polytope.
            2. If the remaining area of the cut polytope is negative, folding or bending the panel is not possible, and the design fails validation.
      ii. Each node in the Fold Graph represents a peak or a valley in the folded structure. There are geometric limits on the amount and direction of folds that may share a node.
         1. For thin substrates, for a node does not link to a cut arc . . .
            a. To Fold flat . . .
            i. The alternating sum of angles of folds around the node must equal zero to avoid tearing. (Kawasaki's Theorem)
            ii. The difference between the number of negative folds and positive folds must be two. (Maekawa's Theorem)
         2. For thick substrates, the number of folds arcs must be balanced with the number of cut arcs to accommodate the thickness of the fold.
      iii. The structure of the folded product must not be self-intersecting.
         1. In the process of folding the product from a flat state to a folded state, no nodes may pass through a polytope.
      iv. Additional validation of the layout and the design is performed by constructing a folding model of the design in subsequent sections.
   j. Setting the Folded/unfolded State.
      i. Define the ‘FoldRoot’
         1. The ‘FoldRoot’ is the FoldGraph Polytope that has the primary attention of the viewer.
         2. May be specified by the Polytope Name
            a. Tagged as FoldRoot.
      ii. Classifying the fold product type
         1. N-tree folding
            a. Classified by Graph Node links
            i. All Fold Arcs are linked to a Node that also is linked to two Cut Arcs.
            1. These may be called CutFoldNodes
            ii. Thin or thick substrate
            iii. Classify by number of CutFoldNodes
            1. Card
            a. No FoldArcs.
            b. May have non-convex CutPath or VisiblePath
            c. Fewer constraints on product substrate.
            2. BiFold
            a. One FoldArc
            b. Unless specified by a tag, for a vertical fold, the FoldRoot is set to the left-most Polytope of the single fold as viewed from the outside.
            c. Unless specified by a tag, for a horizontal fold, the FoldRoot is set to the bottom-most Polytope of the single fold as viewed from the outside.
            d. For a horizontal fold
            3. TriFold
            a. Two FoldArcs
            b. Unless specified by a tag, for a vertical fold, the FoldRoot is set to the Polytope that has links to both FoldArcs.
            4. Box
            a. Multiple FoldArcs.
            b. Unless specified by a tag, the fold root is set to the Polytope that is furthest from the bounding Cut Arcs as determined by the number of links through arcs and neighboring polytopes.
            b. Build the n-Tree
            i. Set each polytope's n-tree-level to 0.
            ii. Set each arc's n-tree-level to 0.
            iii. Set the FoldRoot Polytope n-tree-level to 1.
            iv. Set the current_level=1.
            v. Set settingLevel=true
            vi. While settingLevel is true . . .
            1. settingLevel=false
            2. For Each polytope in the FoldGraph's list of polytopes . . .
            a. For each of the polytope's arc links.
            i. If the other polytope on the paired arc link's n-tree-level equals current_level, Set the polytope's n-tree-level to current_level+1 and set the arc's n-tree-level to and add this polytope to current_level, and add the other polytope to this polytope's child list.
            ii. Else settingLevel=true
            3. Increment current_level.
         2. Directed Graph Folding
            a. Classified by Graph Node links
            i. Contains at least one Graph Node that links to only Fold Arcs.
            1. These may be called FoldNodes.
            ii. Thin Substrate
            iii. These graph sections may be classified as an ‘Origami’ section.
            iv. An n-tree may be constructed using ‘Build the n-Tree’ above.
            v. The n-tree that is constructed is a spanning tree for the Fold Graph. Some Fold Arcs or Bend Arcs are not mapped as links in the spanning tree.
            vi. Non-mapped Fold Arcs or Bend Arcs of the Fold Graph may be found. They will have an n-tree level of zero. A kinematic link will need to be added to the n-tree's geometry to resolve the constraints these Arcs impose on the model.
            1. Define KinematicLink
            a. Has a reference to the Non-mapped Fold Arc or Bend Arc it represents.
            b. Is added to the FoldGraph's KinematicLink list.
            c. Has a function which will insure that the size and shape of each polytope linked through its Arc is preserved when the n-Tree is folded.
            i. This is done by solving for the closest fold angles in adjoining Arcs (linked through Nodes shared with its Arc) that preserve the size and shape of each polytope.
            ii. If no solution is possible, within an error term, the Fold Graph is invalid.
      iii. Determining Fold Order for the Polytope n-tree
         1. The fold order may be specified by the Polytope Name
            a. Tagged as FoldOrder<value>
            b. If not set it may be derived as described below in 3.
            i. This implementation has been tested on common container designs with rectilinear structures where the limit for children in the n-tree is 4.
            c. The process for setting the fold order is a variant of the ‘Carpenter's Rule Problem’
            i. An open problem in geometry until solved in 2000.
            ii. Well-known open-source solutions exist . . .
            iii. https:/en.wikipedia.org/wiki/Carpenter%27s_rule_problem
         2. Determine the Fold Order
            a. Overview of the following process . . .
            i. Sets the fold order so the polytopes on the leaves of the n-tree fold first. (or unfold last).
            1. Except when it is determined that a polytope's unfolding is blocked by another polytope using ray-casting. Then . . .
            a. The blocked polytopes have precedence.
            b. The blocked polytope's fold order is set so they unfold first, from the inside of the fold outward.
            i. Where outside is the direction of the positive folded surface normal of the polytope.
         3. For each polytope in the graph . . .
            a. Set the foldedPosition of the polytope.
            i. Traverse the n-tree building a 4×4 transform matrix
            1. For each level of the n-tree transform the matrix by rotating it around the fold or bend axis by the full fold or bend amount and translate by the center point of each fold or bend.
            ii. Set the foldedPosition of the Nodes linked to the Polytope through its'linked arcs . . .
            1. Set the center of the arc's position that links the polytope to its parent as localOffset.
            2. Set the foldedPosition of the node to the 2D position of the node. Substract the localOfffset from foldedPosition. Set the z value of the foldedPosition to 0.
            3. Transform the foldedPosition of the by the 4×4 transform matrix for that level of the n-tree.
            4. Average all foldedPosition of the Nodes linked to the Polytope and set the polytope's centroid.
         4. Traverse each of the KinematicLinks in the Fold Graph's list.
            a. Iteratively solve the KinematicLinks to preserve the geometry of the polytope.
         5. For each polytope in the graph . . .
            a. Set the folded centroid of the polytope.
            i. Average each foldedPosition of each Node linked to the Polytope through its Arc links.
            ii. Set the Averaged foldedPosition as the polytope's centroid.
            b. Set the folded normal of the polytope.
            i. Traverse the n-tree building a 3×3 transform matrix
            1. For each level of the n-tree transform the matrix by rotation around the fold or bend axis by the full fold or bend amount
            2. Transform a flat normal (0, 0, 1) by rotating by the current 3×3 transform for that level of the n-tree.
         6. Create a temporary list of LockedPolytopes
         7. Set all polytope's lockedDistance to HUGE_VALUE.
         8. For each polytope in the graph . . .
            a. Cast a ray from the polytope's folded centroid.
            i. Cast in the direction of the folded normal.
            1. Find all polytopes that the ray insects (based on its folded position)
            2. Select the closest polytope as the HitPolytope
            3. If the distance to the HitPolytope along the ray is less than 2 substrate thicknesses . . .
            a. If the polytope is not already in the LockedPolytopes list, add it to the LockedPolytopes list and set the polytope's lockedDistance to the found distance.
            4. In cases where the minimum hit distance is zero . . .
            a. If the two polytopes have opposing surface normals, the outward facing surface normal indicates the inside polytope.
            b. else
            i. For thick substrates collisions between polytopes with non-opposing surface normals is an error in the layout. The layout is invalid.
            ii. For thin substrates, the Fold Graph may need to be unfolded slightly to account for collisions. Alternatively, collisions may be sorted based on shared FoldArcs.
            5. Special handling may be applied to those locked polytopes (flaps) that have a radius edge that may rotate into place without locking.
            b. Cast a ray from the polytope's folded centroid.
            i. Cast in the negative direction of the folded normal.
            1. Find all polytopes that the ray insects (based on its folded position)
            2. Select the closest polytope as the HitPolytope
            3. If the distance to the HitPolytope along the ray is less than 2 substrate thicknesses . . .
            a. If the HitPolytope is not already in the LockedPolytopes list, add it to the LockedPolytopes list and add the distance to the LockedPolytopeDistanceKeys.
            9. Sort the LockedPolytopes list by each polytope's lockedDistance.
            10. Set placeholder foldOrder for each polytope . . .
            a. Set CurrentFoldOrder equal the number of polytopes in the Fold Graph*2.
            b. For each n-tree-level in Fold Graph (starting with 1) . . .
            i. For each polytope at that n-tree-level
            1. Set the polytope's foldOrder to CurrentFoldOrder.
            2. Decrement CurrentFoldOrder.
            11. Set the LockedPolytopes fold order
            a. Set CurrentFoldOrder to 5.
            b. For each polytope in the LockedPolytopes list
            i. Set the polytope's fold order to CurrentFoldOrder.
            ii. Set CurrentFoldOrder to CurrentFoldOrder+5.
            12. Set the LockedPolytopes list's parent's fold order
            a. For each polytope in the LockedPolytopes list
            i. Set it's n-tree parent polytope foldOrder to the polytope's foldOrder+1.
            13. Set the LockedPolytopes list's childer's fold order
            a. For each polytope in the LockedPolytopes list
            i. Set CurrentFoldOrder to the polytope's fold order−1.
            ii. For each of the polytope's children . . .
            1. Set the child's fold order to CurrentFoldOrder.
            2. Decrement CurrentFoldOrder by 1.
            14. The resulting foldOrder values will be sequential but will have gaps . . .
            a. To remove the gaps . . .
            i. Build a temporary list of the Fold Graph's polytopes
            ii. Sort the temporary list by the polytope's fold order.
            iii. Remove the gaps in the foldOrder sequence by setting each of the temporary list polytope's fold order to its index in the temporary list.
   k. Constructing an Interactive Model from the n-Tree and Fold Graph for display
      i. The Fold Graph with a contained n-tree is useful for . . .
         1. Validating the design layout based on geometric constraints
         2. Validating the design layout based on physical constraints
         3. Determining relationships between design areas and the physical product components.
         4. Determining the fold order for visualization and user interaction.
      ii. The Fold Graph is not suited as . . .
         1. A scene graph for product visualization
         2. A geometric representation of the product
            a. For rendering geometry
            b. For rendering time-based motion.
      iii. Define the ZigModel (note, please reference the Zig File format patent here and use those naming conventions. Also, reference RasterCover patent as needed. See for example reference U.S. Pat. No. 8,289,317B3 for using behaviors).
         1. zigGeom
            a. Name
            b. Link to Parent zigGeom
            c. Link to Children zigGeoms
            d. List of Behaviors to apply based on the Behavior's reference.
            e. Coordinate Space
            i. May be represented as
            1. Matrix
            a. 4×4 Transform Matrix
            2. Vector
            a. Quaternion 4d vector
            b. Translation 3d vector
            c. Scale 2d Vector
            3. Kinematic
            a. Axis 3d Vector
            b. Amount 1d Scalar
            c. Offset 3d Vector
            4. User Editable
            a. AxisAngle
            i. Rotation Axis*Angle of Rotation
            ii. Also called Rodregues Vector
            b. Translation 3d vector
            c. Scale 2d Vector
            f. Functions to assemble an n-tree
            g. Functions to traverse an n-tree, each element with its own coordinate space.
            h. hRender, a function to render an n-tree to an image with a view transform, and a list of key-value pairs. Each subclass of zigGeom able to display itself within its own coordinate space.
            i. Sets the local transform
            1. Resolves if a Behavior in its list of Behaviors is referenced in the list of key-values, if so . . .
            a. Resolves if there is a time referenced in the list of key-values, if so . . .
            i. Evaluates that behavior for that time, and sets the local coordinate system to that found value.
            b. Else, uses its own local coordinate space.
            2. Else, uses its own local coordinate space.
         2. TransformKey
            a. A coordinate space
            i. Quaternion 4d vector
            ii. Translation 3d vector
            iii. Scale 2d Vector
            b. Time (in seconds)
         3. Behavior
            a. Has a name.
            b. Has a reference to a key-value pair for setting the behavior
            i. Key
            1. The Behavior type name
            ii. Value
            1. This Behaviors name
            c. Has a reference for setting the time
            i. Key
            1. The Behavior time name
            ii. Value
            1. A floating point values for the behavior time in seconds.
            d. A list of transform keys.
         4. zigPreProcess
            a. SourceMap reference
            i. Key-Value reference to an image to preprocess in a list of Key-Values,
            b. DestinationMap reference
            i. Key-Value reference to an image to preprocess in a list of Key-Values,
            c. PreProcess function
            i. Inputs
            1. A local service for temporary object allocation
            2. A Key-Value List
            3. A DestinationSize in {width, height}.
            ii. Actions
            1. Finds a SourceImage in the Key-Value List.
            2. Finds a DestinationImage in the Key-Value List
            a. Creates a temporary copy of the DestinationImage if it has not been copied.
            i. Scales the DestinationImage so that it is close in size to DestinationSize, preserving its aspect ratio.
            b. Replaces the DestinationImage in the Key-Value list with the temporary copy.
            3. Applies its PreProcessing Filter of the SourceImage upon the DestinationImage copy.
            d. zigPreMap: zigPreProcess
            i. Places the SourceImage on the DestinationImage
            ii. Object Variables
            1. Flip
            a. The orientation change to apply to the SourceImage before placement
            i. RotateCW
            ii. RotateCCW
            iii. FlipVertical
            iv. FlipHorizontal
            v. FlipDiagonalLeft
            vi. miFlipDiagonalRight
            2. ResampleType
            a. The method of resampling the SourceImage to change its size before placement
            i. PointSample,
            ii. Gaussian,
            iii. NearestNeighbor,
            iv. Linear,
            v. Cubic,
            vi. CubicBSpline,
            vii. CubicCatmullRom,
            viii. Cubic2,
            ix. Super,
            x. Lanczos,
            xi. Notch
            3. BlendMode
            a. compositeOver
            b. multiply
            c. greater
            4. Invert
            a. If true, invert each pixel in the source image.
            5. SingleChannel
            a. True if a single channel is placed
            6. SourceChannel
            a. If SingleChannel is true...
            i. Use this channel of the SourceImage to place.
            7. DestinationChannel
            a. If SingleChannel is true . . .
            i. Use this channel of the DestinationImage for the placement of the SourceImage.
            8. SourcePosition {x, y}
            a. The position within the SourceImage to position the RegionOfInterest for copying.
            9. SourceRegionOfInterext {height, width}
            a. The size of the portion of the SourceImage for copying into the DestinationImage,
            10. DestinationPosition {x, y}
            a. The position within the DestinationImage to place the filtered SourceImage.
            11. DestinationRegionOfInterext {height, width}
            a. The size of the portion of the DestinationImage for placement of the filtered SourceImage.
            iii. Preprocess Function
            1. Inputs
            a. SourceImage
            b. DestinationImage.
            c.
            2. Action
            a. If SingleChannel
            i. Copy the SourceChannel into a temporary Image called SourceMono
            ii. If Invert is true, then invert SourceMono.
            iii. Determine the size of the SourceImage for its placement with the DestinationRegionOfInteres
            iv. Resample the SourceMono into a temporary copy, ResizedSource, using the ResampleType.
            v.
            b. Else
            i. Determine the size of the SourceImage for its placement with the DestinationRegionOfInterest, applying the SourcePosition, asnd SourceRegionOfInterest.
            ii. Resample the SourceImage into a temporary copy, ResizedSource, using the ResampleType.
            3. Orient ResizedSource according to FlipType
            4. Place ResizedSource into the DestinationImage
            a. Use BlendMode as the transfer method.
            b. User DestinationPosition as an offset for the placement.
            e. zigPreColor: zigPreMap
            i. Colorizes the DestinationImage with PlaceColor, using the SourceImage as a mask.
            ii. Object Variables
            1. PlaceColor
            a. May represent . . .
            i. An RGBA color
            ii. Occlusion, Roughness, Metallic
            iii. A normalized 3-space vector
            iii. Performs similar actions to zigPreMap
            1. Instead of Placing SourceImage into DestinationImage . . .
            a. Used the filtered ResizedSource as a mask to set the PlaceColor into the DestinationImage.
            f. zigPreBump: zigPreMap
            i. Converts a heightmap in SourceImage into a SourceNormalMap for Physically Based Rendering.
            1. Instead of Placing SourceImage into DestinationImage . . .
            a. Places the resampled SourceNormalMap into the DestinationImage.
         5. zigRoot: zigGeom
            a. ViewMatrix
            i. 4×4 view matrix
            b. Preprocesses
            c. List of zigPreProcess
            i. preprocesses to run on the key-value list prior to hRender.
            d. hRender
            i. Make a copy of the input Key-Value list.
            ii. Perform preprocesses
            1. Use the temporary copy of the Key-Value list.
            2. Supply a service to each zigPreProcess in the list for temporary allocation
            a. The scope of the allocations is for the duration of the rendering.
            iii. render an n-tree to an image with its ViewMatrix
            e. setBehavior
            i. Sets the n-tree to a behavior by name
         6. zigKinematic: zigGeom
            a. A zigGeom that solves for a link to another zigGeom across the n-tree link.
            b. Used to resolve the ‘Origami’ class of FoldGraphs or sub-FoldGraphs.
            i. Contains KineLink
            1. reference to another zigGeom.
            ii. Contains a Coordinate Space for the relationship to that reference.
            1. Axis 3d Vector
            2. Amount 1d Scalar
            3. Offset 3d Vector
            iii. Contains KineSolve list
            1. A list of other zigGeoms that need to have their coordinate spaces solved to preserve the fold links.
            iv. Implement a function to solve to preserve the offsets and axis of rotation of its KineLink with the zigGeoms in the KineSolve list.
            1. Iteratively solves for the variable amount of rotation for each zigGeom.
         7. Renderer
            a. Render( )
            i. Takes an input of a polygon, a shader, a destination image, a list of key values
            1. Resolves references for the shader
            2. Samples shader raster output to resolve
            a. Visible surfaces
            b. Transparent surfaces
            c. Blend Mode
            d. Sub-pixel overlap.
         8. Shader
            a. Rasterizes a zigPoly an image buffer.
            b. BlendMode
            i. How to apply the rasterized pixel.
            c. References to
            i. Texture maps held in a list of Key Values
            ii. Variables and modifiers held in a list of Key Values
         9. PbrShader: Shader
            a. A shader that performs Physically Based Rendering using Image Based Lighting.
            i. https://bruop.github.io/ibl/#single_scattering_results
            b. UV texture bindings . . .
            i. The SourceTexture, OcclusionRoughnessMetallic Map, and the EmissiveMap all use the UV0 component of the interpolated vertex.
            ii. SurfaceNormalMap requires that the zigPoly provide a valid surfaceNormal for each interpolated vertex.
            c. Key-Value References
            i. SourceTexture Map
            1. An RGBA texture map representing the surface color of the geometry
            ii. OcclusionRoughnessMetallic Texture Map
            1. Contains . . .
            a. Occlusion channel
            i. Scales the surface color of the geometry
            b. Roughness
            i. Sets the roughness of the surface for each portion of the mapped surface
            c. Metallic
            i. Sets how metal-like the of the surface may be for each portion of the mapped surface
            iii. SurfaceNormalMap
            1. Contains . . .
            a. For each pixel, a 3-space normal to place on the surface of the geometry for each portion of the mapped surface
            iv. EmissiveMap
            1. An RGBA texture map representing the color to emit for surface of the geometry for each portion of the mapped surface.
            v. GlobalSpecularMap
            1. A sphere or cubic environment map with a mapping of the full environment surrounding the model.
            vi. GlobalDiffuseMap
            1. A processed version of the GlobalSpecularMap that maps the diffuse light rays from the full environment surrounding the model.
         10. zigPoly: zigGeom
            a. hRender
            i. Renders polygons to an image by calling a Renderer with its shader, its coordinate system, the view matrix, a list of key-values.
            b. Holds a list of polygons represented as . . .
            i. A list for vertices
            1. Vertex
            a. Position
            b. UV_0
            i. For rendering Texture0
            c. UV_1
            i. For rendering Texture1
            d. Normal
            i. Normal vector for the surface location of the vertex.
            ii. A list for polygons
            1. Polygon
            a. Number of vertices
            b. Index of each vertex . . .
            c. ItsShader
            i. The shader for rendering itself
            iv. Converting the Fold Graph and n-tree into the Zig Format
            1. Define a UniqueName for all Global and Full Textures based on the zigRoot's design layout name.
            2.
            3. Create a zigRoot to hold the model
            a. Set the name of the zigRoot to the name of the designLayout
            b. Begin to build the zigGeom n-tree with zigRoot as the parent, traversing the FoldGraph n-tree . . .
            4. For each polytope, as traversed with the n-tree . . .
            a. Create an mGeom to hold the behavior for this geometry
            i. Name the mGeom
            1. The name of the visible design area associated with the Polytope
            ii. Attach this mGeom to its parent zigGeom in the n-tree.
            iii. Find the tag in the name of the visible design are that defines the ‘outside’ or ‘inside’ naming convention.
            1. Set this as the SideName.
            iv. Convert the local coordinate space of the polytope to a 4×4 matrix
            v. The center of the local coordinate space is the center of the Arc joining this Polytope to its parent Polytope in the n-tree.
            vi. The rotation of the coordinate space is set to identity, or zero rotation in each of the X, Y, Z axis.
            b. Create a new zigPoly(s)
            i. Convert the 2d polytope into a 3d extrusion
            1. Complex subdivision of non-convex polytope into simple convex polygons.
            2. Build faces and edge of the extrusion
            3. Set the texture mapping (U, V) coordinates for each vertex in each polygon in the extrusion such that . . .
            a. The edge has a U, V map that represents it as a continuous surface.
            i. This mapped to {0, 0) through {1, 1}.
            b. Each vertex in the outside face of the extrusion is mapped to its location in the design layout.
            i. Scaled to {0, 0} through {1, 1} based on the height and width of the full outer bleed region of the design layout.
            c. Each vertex in the inside face of the extrusion is mapped to its location in the design layout.
            i. Scaled to {0, 0} through {1, 1} based on the height and width of the full outer bleed region of the design layout.
            ii. Each U component is then set to 1.0−U.
            4. Modify the region of the extrusion where the source polytope is linked to a FoldArc or a BendArc. Let this region be called the ‘Hinge’
            a. For a FoldArc, modify the hinge so it represents the scored substrate, there is a single hinge path, and no collisions of surfaces as the hinge folds.
            b. For a Bend Arc, modify the hinge sot that it represents the bending substrate . . .
            i. Build an array of scalars mapped to each vertex in the hinge that holds the contribution of the Polytope's local coordinate space, allowing each vertex to have mixed contribution of local coordinates and parent coordinate spaces.
            ii. Create a separate zigPoly for the outside face of the extrusion, the inside face of the extrusion and the edge of the extrusion.
            iii. Name the zigPoly
            1. The name of the visible design area associated with the Polytope with a modifier tag appended.
            a. Determine the SideName
            b. Use the found SideTag
            i. Inside SideTag
            ii. Outside SideTag
            iii. Edge SideTag.
            c. Set the SideName with the SideTag.
            d. Append the SideName to the name for the zigPoly.
            iv. Set the zigPoly local coordinate space
            1. To the converted local space, above.
            v. Attach the zigPoly to the mGeom behavior holder above.
            vi. Set itsShader
            1. Set to a PbrShader
            a. Set the PbrShader references
            i. Use the UniqueName+SideName+FullTag for the SourceTexture reference name.
            ii. Use the UniqueName+SideName+FullTag+‘_orm’for the OcclusionRoughnessMetal Texture reference name.
            iii. Use the UniqueName+SideName+FullTag+‘_bump’ for the NormalMapTexture reference name.
            iv. Use the UniqueName+SideName+FullTag+‘_bump’ for the EmmissiveMapTexture reference name.
            b. Set the PBR scalars to represent the material properties of the un-modified substrate.
            5. Building the Lighting Environment
            a. The lighting environment may be designed in the same manner that is used in product photography
            i. Main direct light(s)
            1. Positioned to show the form of the product.
            2. Area lighting that offers good contrast for reflective and metallic surfaces.
            3. Provides positioning for soft synthetic cast shadows.
            ii. Key Light(s)
            1. Lights that enhance the edge of the product based on view angle.
            2. May provide area lighting to enhance reflective and metallic surfaces
            3. Provides relief for embossed and debossed portions of the product.
            iii. Ambient light
            1. Sufficient to illuminate and visually explain the shadowed area of the product.
            b. Capturing the lighting environment as a Global SpecularMap for Image Based Lighting.
            i. Produced by generative AI image services
            1. Text requests for input
            a. Description of the spherical surface to reflect the lighting
            b. Enumeration of each light location and area shape.
            c. Description of the sharpness and photographic realism required.
            ii. Produced by photography
            1. Reflecting Sphere
            a. A reflecting sphere may be placed in the desired lighting environment and photographed, producing a digital image.
            2. Motion-controlled Photography
            a. A drone or robotic arm may be used to capture a spherical panorama of a physical lighting environment.
            i. A spherical panorama (mapping by latitude and longitude of a sphere) may be re-mapped to a reflecting sphere.
            ii. See PrintCutFoldEmbellish\Light ingEnvironments\Drone\PanoToSphere
            c. Generating a Global DiffuseMap
            i. A Global SpecularMap may be used as input to a filter which samples it to solve lighting on a diffuse sphere.
            1. See PrintCutFoldEmbellish\LightingEnvironments\Drone\ReflectToDiffuse
            d. Filtering the Global Image Based Lighting Maps
            i. Additional filtering of the Global SpecularMap and Global DiffuseMap may be performed to match the output of physical photographs of the product.
            6. Build time-based animations for the Interactive Model
            a. A single animation may operate on many zigGeoms within the n-tree.
            b. Sets of zigBehavior objects with matching Keys-Values may be used to set time and motion across the n-tree.
            c. Define a UniqueName for all Behaviors based on the zigRoot's design layout name.
            d. Building the zigBehaviors for Folding
            i. For each Polytope in the FoldGraph that is not the FoldRoot . . .
            1. With the FoldArc or BendArc that attaches the Polytope to its parent Polytope.
            a. Create a new zigBehavior
            b. Set the zigBehavior's name
            i. Use the UniqueName and add a tag for the folding action such as ‘_fold’
            c. Find the zigGeom in the zigRoot with the same name as the name of the visible design area associated with the Polytope,
            d. Create a TransformKey for the start key
            i. Set the Quaternion to Identity (no rotation)
            ii. Set the Translation to {0, 0, 0}
            iii. Set the Scale to {1, 1, 1}
            e. Add the start key to the zigBehavior
            f. Create a TransformKey for the end key
            i. Set the Quaternion to rotate the FoldArc's bend amount around the axis formed by the FoldArc's path.
            ii. Set the Translation to {0, 0, 0}
            iii. Set the Scale to {1, 1, 1}
            g. Add the end key to the zigBehavior
            h. Add the zigBehavior to the found zigGeom's zigBehavior list.
            e. Building zigBehaviors for Display
            i. Behaviors may be crafted that show how the rendered surface of the product reflects light.
            1. These may be determined by the lighting environment for the model and the orientation of the planes of the model.
            2. Subtle movement toward and away from the reflecting angle of the surface and key lights in the image-based lighting model may be used.
            7. Build preprocessing filters
            a. Why Pre-processing is necessary
            i. Moves simple compositing and image operations from the time-critical pixel-level pixel and sub-pixel rendering functions.
            ii. Allows for a constant Physically Based Rendering model for multiple products with complex embellishment layers.
            iii. Allows for a simpler geometry model by handling sub-design areas through pre-processing rather than additional geometry layers.
            b. Building the pre-processing objects
            i. For each Polytope in the FoldGraph that is not the FoldRoot . . .
            1. Find the BleedPath for the sub-design attached to the Polytope.
            a. Find the bounds of the BleedPath, place in BleedBounds {x, y, width, height}
            2. Find the VisiblePath for the sub-design attached to the Polytope.
            a. Find the bounds of the VisiblePath, place in VisibleBounds {x, y, width, height}
            3. Find the zigGeom in the zigRoot with the same name as the name of the visible design area associated with the Polytope.
            4. To Create a Preprocess for the PBR SourceTexture . . .
            a. Create a zigPreMap
            b. For each SideTag . . .
            i. Find the SideName
            ii. Create a zigPreMap
            iii. Set the FullSourceTexture name for the DestinationReference
            iv. Set the name of the zigGeom+SideName as the SourceReference for the Preprocess.
            v. Set the name of the zigPreMap to SourceReference name.
            c. Set the zigPreMap variables . . .
            i. Set the SourcePos to BleedBounds{x, y]−VisibleBounds{x, y}
            ii. Set the SourceROI to VisibleBounds{width,height}
            iii. Set the DestinationPos to VisibleBounds{x, y}
            iv. Set the DestinationROI to VisibleBounds{width,height}
            v. Set the FlipMode to the FlipTag for the design.
            vi. If the Full Source Texture should show set the BlendMode to multiply
            vii. Else set the BlendMode to CompositeOver
            d. Attach the ZigPreMap(s) to the zigRoot for Preprocessing.
            5. For each embellishment mode
            a. Create preprocessing objects to convert an image representing the embellishment area to set values representing that embellishment type in with each of the full PBR maps as destinations.
Conversion of the zigRoot to a client rendering model:
   l. The zigRoot may be converted directly into widely used binary file formats that support real time PBR rendering on the client, such as GLTF and GLB.
      i. Proprietary extensions within an open-source format will preserve key-value references and embedded tags within the GLTF or GLB model
      ii. Proprietary extensions and open-source extensions within an open-source format will support Image Based Lighting. The rendering flow:
   m. The zigRoot: hRender function is called to render a frame of an image
      i. A behavior and time may be set
         1. This will set the transforms during render time
      Ii. A Key-Value list may be supplied
         1. That sets external full or sub-design textures for customizing the ornamentation of each embellishment type.
         2. Set the global lighting maps for PBR rendering.
      iii. During rendering . . .
         1. The zigRoot will copy the key-value list and pre-process all the sub-design areas for each of the each embellishment types.
            a. These will be resolved into full texture maps for PBR rendering.
         2. The behavior and time will be resolved for each rendering frame.
         3. The image will be rendered using a Physically Based Rendering model that matches each embellishment type, using the supplied lighting model.
   n. The rendered frame is returned.
Product Visualization for the User:
   o. The user interacts with a client application (use existing disclosures here)
      i. A digital component-based file format is transmitted to the client
         1. Such as a converted GLB model with embedded key-value references.
      ii. The client application provides a user interface for changing and updating the key-value pairs within the Digital Model.
         1. The client application constrains the user inputs that may be manufactured.
         2. The client application presents single images of the user's changes by calling rendering functions with the valid key-value list.
         3. The client application presents animated images of the user's changes by calling rendering functions with the valid key-value list.
Production of Physical Product:
   p. Modifications to key-value pairs in the Digital Model are used to update the Product Description.
   q. The Product Description is used to generate Manufacturing Instructions.
   r. The Product is manufactured.
Validation of the Interactive Model and Descriptive Layout File against the Physical Product
   s. Images may be taken of the Physical Product in controlled lighting and a controlled viewpoint.
   t. Images may be compared using computational methods with the lighting and viewpoint of the Interactive Model.
      i. Geometric shape differences may be used to update the Descriptive Layout File.
      ii. Surface lighting differences may be used to solve for settings in the Physically Based Rendering model.
         1. A delta change is made for a variable in the PBR model.
         2. It is compared against the Physical Product Image.
            a. If the difference is within the error term for the variable, progress to the next variable.
            b. If all variables have been adjusted, validation and adjustment is complete.
         3. A delta change in the Physical Product Image is correlated with the delta change in the PBR mode.
      iii. The correlated data is used to update the PBR model.
      iv. The delta change is recorded, and the process resumes as above.

### 16.0. Example Information Flow

FIG. 4B is a block diagram of the information flow in the presented system. As shown in FIG. 4B, the initial information is provided or stored in a Descriptive Layout File 452. Information from File 452 is provided and used to generate a Fold Graph 454. Based on the information in Fold Graph 454, a Geometry Verification 456 is performed, and an Interactive Model 458 is generated. Based on, at least in part, information stored in Interactive Model 458, a Unified Data Container 460 is generated.

The information stored in Unified Data Container 460 may be displayed on a User Display 462. A user may interact with User Display 462, and User Interactions 464 may be stored in, for example, Unified Data Container 460.

Based on User Interactions 464 (and, for example, the information stored in Unified Data Container 460), Production Instructions 466 are generated.

Production Instructions 466 are sent to, for example, a manufacturer to apply a Physical Production 468 process to manufacture a physical product.

Information about the manufactured physical product may be transmitted to a Verification of User Display 470 to allow verifying quality of the manufactured product.

The verification results may be transmitted from Verification of User Display 470 to a Verification of Descriptive Layout File 472 and stored in File 472.

In some implementations, the information flow process ends at an End Point 474. However, in some other implementations, some of the information may be transmitted back to other components, such as components depicted in FIG. 4B, or to components not depicted in FIG. 4B, but contemplated in practical implementations of the presented approach.

### 17.0. Example Computer Environments

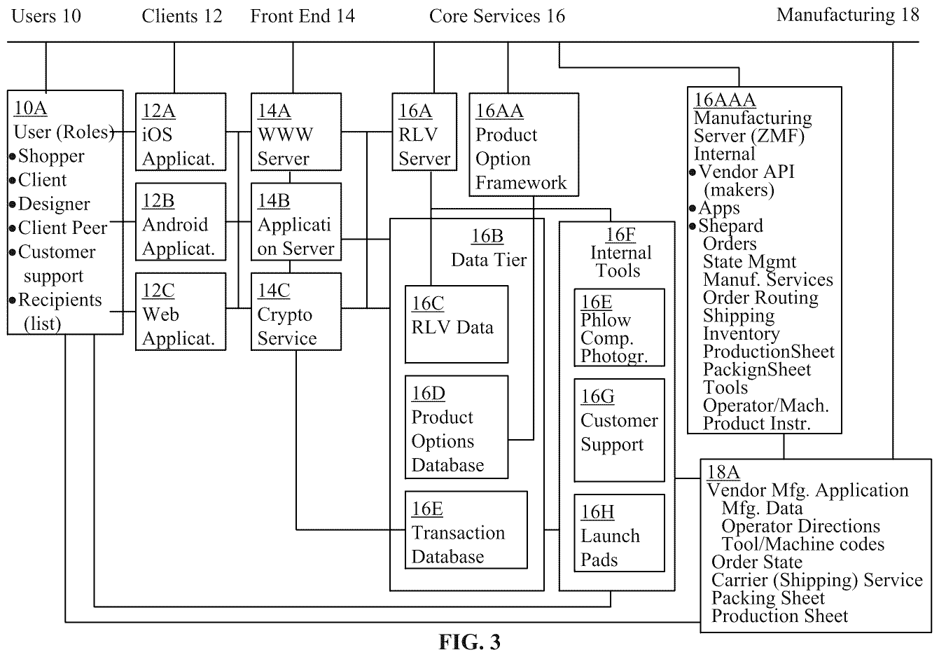

In some embodiments, the presented approach is implemented in a computer-based platform. The platform allows users, designers, customers, and support engineers to, for example, design and create digital product designs. FIG. 3 describes a computer environment for creating digital designs, manufacturing products, etc.

A digital design for a product may be captured in, for example, product description data. A hyperlink to the location can be created and transmitted from the collaboration platform to a manufacturing server, causing the server to generate a final product based on the digital design.

A product may be digital, such as a digital gift card, or a combination of physical and digital, such as a physical or digital t-shirt.

FIG. 3 is a block diagram showing an example computer environment. In FIG. 3, users 10 are individuals who create and design digital designs of products; clients 12 correspond to software applications configured to facilitate communications between users 10 and front-end servers 14; core services 16 correspond to software applications and tools configured to facilitate creating and designing of the digital designs and generating manufacturing instructions for manufacturing final products based on the digital designs; and manufacturing 18 corresponds to manufacturing servers and applications configured to manufacture, or cause manufacturing, the final products, and the like.

Each user 10 may use its own or a shared computer device. In some embodiments, examples of user 10 are determined based on the roles that may be assigned to the users. Examples 10A of roles may include a shopper, a client, a designer, a client peer, a customer support engineer, a recipient, and the like.

Clients 12 in FIG. 3 refer to client applications implemented in client servers 14 and configured to support requests received from users 10A. Non-limiting examples of clients 12 may include iOS applications 12A, Android applications 12B, Web applications 12C, and the like.

Front and end servers 14 refer to computer-based servers configured to process requests received from clients 12 and, in many cases, interact with core services 16 to resolve these requests further. Examples of front-end servers 14 include one or more WWW servers 14A, one or more application servers 14B, and one or more cryptographic servers 14C. Cryptographic servers 14C may be configured to provide cryptographic services for encrypting/decrypting, transmitting, or otherwise communicating data between the entities depicted in FIG. 1.

Core services 16 in FIG. 3 refers to servers and services implemented in a role-based collaboration platform configured to provide functionalities for creating and designing digital designs, handling collaboration requests, and facilitating the customization requests received from users 10.

In some embodiments, a customization process performed by a user, such as user 10, intended to generate a digital design of a customized product, is captured in so-called product description data, which may be translated into a manufacturing description comprising product and manufacturing instructions.

The product and manufacturing instructions may include digital design specifications, data, and code needed to manufacture a custom product. That may include instructions for generating, for example, a 3D geometry for digital final products. This may also include generating instructions for creating 2D and 3D patterns that can be used to cut, cast, or form physical or digital components of final products. The patterns may be parametric, i.e., they may have parameters that, through encoded relationships, adjust the form of the pattern for a specific need.

For instance, a set of 2D patterns for a t-shirt graded based on size may be converted into a parametric pattern by interpolating the grade curvatures. A single parametric value, usually called a ‘size,’ may set the automatic grading.

The product instructions may also include 2D and 3D models used to form, through additive manufacturing or subtractive manufacturing, portions of a product. The models may be parametric, i.e., they may have parameters that, through coded relationships, adjust the model's form to meet a specific need. For instance, a set of 3D models may represent a bike helmet. Each model may fit a statistically normed human head of a particular age. A coded relationship between the models may allow for interpolating the set of models for a specific age. A single parametric value may set the automatic interpolation. The single parametric value, in this case, is usually called an ‘age.’

The product instructions may also include material properties, such as the physical or digital material used to form a product from a pattern. Some material properties may be parametric, i.e., they may be selected or changed during manufacturing.

The properties may also include a body color. For instance, the color of a fabric may be selected for manufacturing a t-shirt. According to another example, the plastic color may be chosen for manufacturing a bike helmet.

The properties may also include a body texture, such as the fabric weave of a t-shirt, which can be specified as smooth or slubby. For instance, the surface of a plastic bike helmet may be polished or satin. Each property is necessarily specific to each class of materials. Examples of materials and properties may include a fabric (such as a weave or knit type, a fiber type (e.g., cotton, wool, flax, polyester, polypropylene), a thread size, a thread count, a color, an integral design (e.g., ikat, knit, tapestry, etc.), a bolt width, a selvage type, a surface (e.g., hand), and the like.

Referring again to FIG. 3, in some embodiments, core services 16 refer to services implemented in a role-based collaboration platform. In the example, core services 16 may be provided by one or more real-view (RLV) servers 16A and a product option framework 16AA. RLV servers 16A and product options framework 16AA may use one or more data tier databases 16B, including RLV Data 16C, a product options database 16D, a transaction database 16E, and the like.

In some embodiments, core services 16 may also utilize internal tools 16F, such as computational photographic tools 16E, customer support tools 16G, launch pads tools 16H, etc.

Product option framework 16AA is also called a persistent design data framework. The framework data may include a product options set, which may include a set of product options pertaining to a specific product type. It usually contains the product instructions (e.g., collaboration components 106 in FIG. 2) for manufacturing or producing the product.

In some embodiments, the product options framework 16AA is configured to provide services for transforming ProductOption key/value pairs (i.e., manufacturing constraints) from one product to another. Transforming the ProductOption key/value pairs from one product to another may require, for example, transforming the color space (i.e., sRGB to CMYK US Web Coated (SWOP) v2), converting an image from raster to vector, and resizing the image to fit.

In some embodiments, the product option set includes logic to enumerate each customizable option in a manner that presents a complete user interface for changing the parametric product instructions.

The instructions for manufacturing a customized product are usually parametric. The parameters include the size of the customized product (this can be multi-dimensional and include width, height, and depth). The parameters may also relate to human size or age. The parameters may also be custom and based on biometric information.

In some embodiments, a product option may be represented as a key/value pair. The key/value pair is a label that may span individual products and represent a class of products. The keys of pairs may include a material type, a color, a size, and other similar details.

The value in a key/value pair is a specific, discrete, or continuous value that sets a manufacturing instruction. Examples of discrete (enumerated) values may include a discrete type of fabric such as cotton, cotton-polyester blend, silk, and the like. The discrete values may also include specific colors, such as white, navy, black, and the like.

Examples of continuous values of key/value pairs may include a single element, such as length or a ribbon, a vector, such as the size of a frame for a print (width (in inches) or height (in inches)), or the size of a box for the European countries, such as a size of a box for the EU (width (in millimeters), height (in millimeters), depth (in millimeters)).

The values may also refer to a known file type, such as an image for the t-shirt design, an embroidery file for the back of a jacket, an engraving design for a bracelet, and the like.

In some embodiments, values in key/value pairs may include a set of graphic primitives for a design, such as an image, a line, a circle, a rectangle, a text, a group, and the like.

The product option key values may have default values. Default values are pre-set values that produce a product without requiring changes to key/value pairs through customization. When key values are changed, they may produce a product option framework event chain. A product options framework event chain is a journal of each key-value change ordered in time.

A product option key value may represent a product type. Using this option type, one product type may be associated with another through a well-known relationship.

In some embodiments, a product options framework event chain includes one or more products, and the chain may represent or memorialize an event that has occurred. The products may represent or memorialize an event. Examples of events may include weddings, birthdays, anniversaries, graduations, national holidays, reunions, and the like.

In some embodiments, a product option set event chain includes a key/value pair that encodes the following product in the chain. For example, an invitation may be chained to an RSVP card. A key value may also encode the role of the chained event. For example, a chained RSVP card key value may include a recipient of the invitation as the sender role for the RSVP card.

A key-value pair may also encode the shared properties used to set the chained product's properties. For instance, a design for the invitation may be shared with the RSVP card. A key value may also encode the timing for the chained product. Typically, the event chain properties are custom (e.g., parametric), and a product designer may change them to fit a specific product set.

In an embodiment, a product option framework is configured to generate a user interface for the product option framework. Accordingly, each product option set is associated with logic and code to build a user interface element for each parametric product option. Furthermore, each product options set contains style hints so that each user interface element may be artfully placed to produce a high-quality user experience.

Typically, user interface elements are designed to match each class of values in all products covered by a product options framework. New user interface elements may be added as the product categories expand. The user interface elements may include a design view, a color editor, a font editor, a size selector, a texture selector, a text editor, a fabric swatch selector, a product configurable image, and the like.

In some embodiments, a product options framework cooperates with a user product renderer that may be implemented in, for example, a RealView server 16A. The user product renderer may be configured to render views of a custom product as it is already manufactured. Typically, it uses a product option set of key values as input. It creates one or more run-time assets using computational photography of the manufactured product.

### 18.0. Implementation Mechanisms

Although the flow diagrams of the present application depict a particular set of steps in a specific order, other implementations may use fewer or more steps in the same or different order than those shown in the figures.

According to one embodiment, the techniques described herein are implemented by one or more special-purpose computing devices. The special-purpose computing devices may be hard-wired to perform the techniques or may include digital electronic devices such as one or more application-specific integrated circuits (ASICs) or field programmable gate arrays (FPGAs) that are persistently programmed to perform the techniques or may include one or more general purpose hardware processors programmed to perform the techniques under program instructions in firmware, memory, other storage, or a combination. Such special-purpose computing devices may combine custom hard-wired logic, ASICs, or FPGAs with custom programming to accomplish the techniques. Special-purpose computing devices may include desktop computer systems, portable computer systems, handheld devices, networking devices, or any other device that incorporates both hard-wired and programmable logic to implement the techniques.

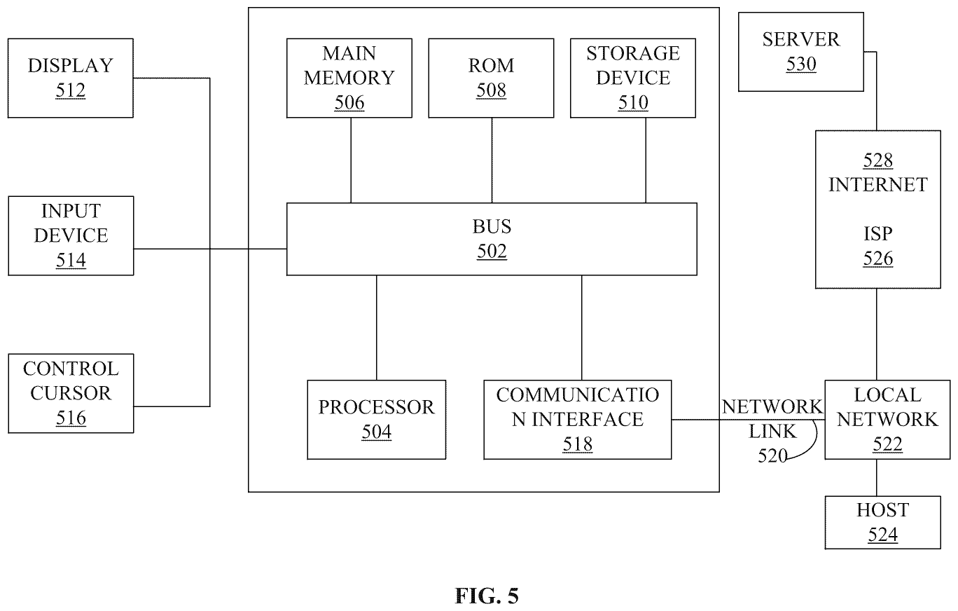

FIG. 5 is a block diagram that depicts an example computer system 500 upon which embodiments may be implemented. Computer system 500 includes a bus 502 or other communication mechanism for communicating information and a processor 504 coupled with bus 502 for processing information. Computer system 500 also includes a main memory 506, such as a random-access memory (RAM) or other dynamic storage device, coupled to bus 502 for storing information and instructions to be executed by processor 504. Main memory 506 may also be used to store temporary variables or other intermediate information during the execution of instructions to be executed by processor 504. Computer system 500 includes a read-only memory (ROM) 508 or other static storage device coupled with bus 502 for storing static information and instructions for processor 504. A storage device 510, such as a magnetic disk or optical disk, is provided and coupled to bus 502 for storing information and instructions.

Computer system 500 may be coupled via bus 502 to a display 512, such as a cathode ray tube (CRT), for displaying information to a computer user. Although bus 502 is illustrated as a single bus, it may actually comprise one or more buses. For example, bus 502 may include, without limitation, a control bus by which processor 504 controls other devices within computer system 500, an address bus by which processor 504 specifies memory locations of instructions for execution, or any other type of bus for transferring data or signals between components of computer system 500.

An input device 514, including alphanumeric and other keys, is coupled to bus 502 for communicating information and command selections to processor 504. Another type of user input device is cursor control 516, such as a mouse, a trackball, or cursor direction keys for communicating direction information and command selections to processor 504 and controlling cursor movement on display 512. This input device typically has two degrees of freedom in two axes, a first axis (e.g., x) and a second axis (e.g., y), that allows the device to specify positions in a plane.

Computer system 500 may implement the techniques described herein using customized hard-wired logic, one or more ASICs or FPGAs, firmware and/or program logic, or computer software which, in combination with the computer system, causes or programs computer system 500 to be a special-purpose machine. According to one embodiment, these techniques are performed by computer system 500 in response to processor 504 executing one or more sequences of instructions contained in main memory 506. Such instructions may be read into main memory 506 from another computer-readable medium, such as storage device 510. Execution of the sequences of instructions contained in main memory 506 causes processor 504 to perform the process steps described herein. In alternative embodiments, hard-wired circuitry may be used in place of or in combination with software instructions to implement the embodiments. Thus, embodiments are not limited to any specific combination of hardware circuitry and software.

The term “computer-readable medium” refers to any medium that provides data that causes a computer to operate in a specific manner. In an embodiment implemented using computer system 500, various computer-readable media are involved, such as providing instructions to processor 504 for execution. Such a medium may take many forms, including, but not limited to, non-volatile media and volatile media. Non-volatile media include, for example, optical or magnetic disks, such as storage device 510. Volatile media includes dynamic memory, such as main memory 506. Typical forms of computer-readable media include, for example, a floppy disk, a flexible disk, hard disk, magnetic tape, or any other magnetic medium, a CD-ROM, any other optical medium, a RAM, a PROM, and EPROM, a FLASH-EPROM, any other memory chip, or memory cartridge, or any other medium from which a computer can read.

Various forms of computer-readable media may be involved in carrying one or more sequences of instructions to processor 504 for execution. For example, the instructions may initially be carried on a magnetic disk of a remote computer. The remote computer can load the instructions into its dynamic memory and send them over a telephone line using a modem. A modem local to computer system 500 can receive the data on the telephone line and use an infrared transmitter to convert the data to an infrared signal. An infrared detector can receive data from the infrared signal, and appropriate circuitry can place the data on bus 502. Bus 502 carries the data to main memory 506, from which processor 504 retrieves and executes the instructions. The instructions received by main memory 506 may optionally be stored on storage device 510 before or after execution by processor 504.

Computer system 500 also includes a communication interface 518 coupled to bus 502. Communication interface 518 provides a two-way data communication link to a network link 520, which is connected to a local network 522. For example, communication interface 518 may be an integrated service digital network (ISDN) card or a modem to connect data to a corresponding telephone line. Another example is communication interface 518, a local area network (LAN) card that provides a data communication connection to a compatible LAN. Wireless links may also be implemented. In any such implementation, communication interface 518 sends and receives electrical, electromagnetic, or optical signals that carry digital data streams representing various types of information.

Network link 520 typically provides data communication to other data devices through one or more networks. For example, network link 520 may provide a connection through local network 522 to a host computer 524 or data equipment operated by an Internet Service Provider (ISP) 526. ISP 526 provides data communication services through the worldwide packet data communication network, now commonly called the “Internet” 528. Local network 522 and Internet 528 both use electrical, electromagnetic, or optical signals that carry digital data streams.

Computer system 500 can send messages and receive data, including program code, through the network(s), network link 520, and communication interface 518. In the Internet example, server 530 might transmit a requested code for an application program through Internet 528, ISP 526, local network 522, and communication interface 518. The received code may be executed by processor 504 as it is received and/or stored in storage device 510 or other non-volatile storage for later execution.

In the foregoing specification, embodiments have been described concerning numerous specific details that may vary from implementation to implementation. Thus, the sole and exclusive indicator of what is, and what the applicants intend to be, is the approach, which is the set of claims issued from this application in the specific form in which such claims are issued, including any subsequent corrections. Hence, no limitation, element, property, feature, advantage, or attribute that is not expressly recited in a claim should limit the scope of such claim in any way. Accordingly, the specification and drawings should be regarded in an illustrative rather than a restrictive sense.

What is claimed is:

1. A computer-implemented method for creating and manufacturing interactive display products with layered embellishments, the method comprising:
receiving a layout file in a format capable of containing vector paths, layers, and human-readable annotations;
processing the layout file to extract a design area paths of a design including safe, visible, and bleed areas, as well as physical geometry paths such as cut paths and fold paths;
generating annotated data and instructions for folding and cutting a product based on the fold paths and cut paths, including fold order and fold geometry;
constructing a 3D model of the product from the annotated data, wherein the 3D model includes representations of a physical substrate, material type, and thickness;
based, on the annotated data, the 3D model, folding-cutting instructions and one or more embellishments, generating an annotated design file; and
based on the annotated design file, generating automated manufacturing instructions.

2. The method of claim 1, further comprising:
supporting various embellishment types including foil printing, engraving, etching, and blocking, and processing combinations of these embellishments;
performing output verification to ensure that the product matches a design intent, including automated verification methods;
preprocessing rendering maps for different embellishment types and rendering them in hardware on a client device;
validating a foldability of the design by constructing a graph and checking for self-intersections and locked areas;
using physically based rendering to represent various embellishment types in a unified rendering model;
allowing users to interactively change key values and view an image of a valid physical product that may be manufactured.

3. The method of claim 2, wherein the layout file is selected from the group consisting of PDF, SVG, and OBJ formats;
wherein the design area paths include safe, visible, and bleed areas, and the physical geometry paths include cut paths and fold paths.

4. The method of claim 2, further comprises:
annotating the layout file with human-readable annotations that include layer names, path names, and spot colors;
generating a fold order and fold geometry based on the fold paths;
supporting various embellishment types, including foil printing, engraving, etching, and blocking.

5. The method of claim 2, wherein the 3D model includes representations of the physical substrate, material type, and thickness.

6. The method of claim 2, further comprising processing combinations of different embellishment types;
performing output verification to ensure that the product matches the design intent;
wherein the output verification includes automated verification methods;
wherein the rendering maps are rendered in hardware on a client device.

7. The method of claim 2, further comprising:
preprocessing rendering maps for different embellishment types;
validating a foldability of the design by constructing a graph and checking for self-intersections and locked areas;
wherein physically based rendering is used to represent various embellishment types in a unified rendering model.

8. One or more non-transitory, computer-readable storage media for creating and manufacturing interactive display products with layered embellishments, the media storing one or more computer instructions which, when executed by one or more processors, cause the one or more processors to perform:
receiving a layout file in a format capable of containing vector paths, layers, and human-readable annotations;
processing the layout file to extract a design area paths of a design including safe, visible, and bleed areas, as well as physical geometry paths such as cut paths and fold paths;
generating annotated data and instructions for folding and cutting a product based on the fold paths and cut paths, including fold order and fold geometry;
constructing a 3D model of the product from the annotated data, wherein the 3D model includes representations of a physical substrate, material type, and thickness;
based, on the annotated data, the 3D model, folding-cutting instructions and one or more embellishments, generating an annotated design file; and
based on the annotated design file, generating automated manufacturing instructions.

9. The one or more non-transitory, computer-readable storage media of claim 8, storing additional instructions for:
supporting various embellishment types including foil printing, engraving, etching, and blocking, and processing combinations of these embellishments;
performing output verification to ensure that the product matches a design intent, including automated verification methods;
preprocessing rendering maps for different embellishment types and rendering them in hardware on a client device;
validating a foldability of the design by constructing a graph and checking for self-intersections and locked areas;
using physically based rendering to represent various embellishment types in a unified rendering model;
allowing users to interactively change key values and view an image of a valid physical product that may be manufactured.

10. The one or more non-transitory, computer-readable storage media of claim 9,
wherein the layout file is selected from the group consisting of PDF, SVG, and OBJ formats;
wherein the design area paths include safe, visible, and bleed areas, and the physical geometry paths include cut paths and fold paths.

11. The one or more non-transitory, computer-readable storage media of claim 9, storing additional instructions for:
annotating the layout file with human-readable annotations that include layer names, path names, and spot colors;
generating a fold order and fold geometry based on the fold paths;
supporting various embellishment types, including foil printing, engraving, etching, and blocking.

12. The one or more non-transitory, computer-readable storage media of claim 9, wherein the 3D model includes representations of the physical substrate, material type, and thickness.

13. The one or more non-transitory, computer-readable storage media of claim 9, storing additional instructions for:
processing combinations of different embellishment types;
performing output verification to ensure that the product matches the design intent;
wherein the output verification includes automated verification methods;
wherein the rendering maps are rendered in hardware on a client device.

14. The one or more non-transitory, computer-readable storage media of claim 9, storing additional instructions for:
preprocessing rendering maps for different embellishment types;
validating a foldability of the design by constructing a graph and checking for self-intersections and locked areas;
wherein physically based rendering is used to represent various embellishment types in a unified rendering model.

15. An apparatus for creating and manufacturing interactive display products with layered embellishments, comprising:
a file input module configured to receive a layout file in a format capable of containing vector paths, layers, and human-readable annotations;
a processing module configured to process the layout file to extract design area paths of a design, including safe, visible, and bleed areas, as well as physical geometry paths such as cut paths and fold paths;
an annotation and instruction generation module configured to generate annotated data and instructions for folding and cutting a product based on the fold paths and cut paths, including fold order and fold geometry;
a 3D model construction module configured to construct a 3D model of the product from the annotated data, wherein the 3D model includes representations of a physical substrate, material type, and thickness;
a design file generation module configured to generate an annotated design file based on the annotated data, the 3D model, folding-cutting instructions, and one or more embellishments; and
a manufacturing instruction module configured to generate automated manufacturing instructions based on the annotated design file.

16. The apparatus of claim 15, further comprising:
an embellishment support module configured to support various embellishment types including foil printing, engraving, etching, and blocking, and to process combinations of these embellishments;
an output verification module configured to perform output verification to ensure that the product matches a design intent, including automated verification methods;
a preprocessing module configured to preprocess rendering maps for different embellishment types and render them in hardware on a client device;
a foldability validation module configured to validate a foldability of the design by constructing a graph and checking for self-intersections and locked areas;
a rendering module configured to use physically based rendering to represent various embellishment types in a unified rendering model; and
a user interaction module configured to allow users to interactively change key values and view an image of a valid physical product that may be manufactured.

17. The apparatus of claim 16,
wherein the file input module is further configured to receive the layout file in a format selected from the group consisting of PDF, SVG, and OBJ; and
wherein the processing module is further configured to extract design area paths including safe, visible, and bleed areas, and physical geometry paths including cut paths and fold paths.

18. The apparatus of claim 16, further comprising:
an annotation module configured to annotate the layout file with human-readable annotations that include layer names, path names, and spot colors;
a fold order generation module configured to generate a fold order and fold geometry based on the fold paths;
and wherein the embellishment support module is further configured to support various embellishment types, including foil printing, engraving, etching, and blocking.

19. The apparatus of claim 16, wherein the 3D model construction module is further configured to include representations of the physical substrate, material type, and thickness.

20. The apparatus of claim 16,
wherein the embellishment support module is further configured to process combinations of different embellishment types;
wherein the output verification module is further configured to perform output verification to ensure that the product matches the design intent, including automated verification methods; and
wherein the preprocessing module is further configured to render the rendering maps in hardware on a client device.
